(19) United States
(12) Patent Application Publication
(10) Pub. No.: US 2025/0240945 A1
(43) Pub. Date: Jul. 24, 2025

(54) SEMICONDUCTOR DEVICE

(71) Applicant: Samsung Electronics Co., Ltd., Suwon-si (KR)

(72) Inventors: Jinseong LEE, Suwon-si (KR); Kanguk KIM, Suwon-si (KR); Jihun KIM, Suwon-si (KR); Jiuk JANG, Suwon-si (KR); Shinwoo JEONG, Suwon-si (KR); Yuseok CHOI, Suwon-si (KR)

(73) Assignee: Samsung Electronics Co., Ltd., Suwon-si (KR)

(21) Appl. No.: 18/764,505

(22) Filed: Jul. 5, 2024

(30) Foreign Application Priority Data
Jan. 22, 2024 (KR) 10-2024-0009330

(51) Int. Cl. H10B 12/00; H01L 23/532

(52) U.S. Cl. CPC H10B 12/482; H01L 23/53266; H10B 12/0335

(57) ABSTRACT

A semiconductor device includes a substrate including a first region and a second region, a first active pattern and a second active pattern on the first and second regions of the substrate, respectively, a bit line structure extending in a horizontal direction, the bit line structure including, a lower conductive structure having first conductive patterns and second conductive patterns alternately and repeatedly arranged in the horizontal direction, the first conductive patterns containing polysilicon doped with first impurities and second impurities, and the second conductive patterns containing polysilicon doped with third impurities, and an upper conductive structure on the lower conductive structure and including a third conductive pattern, a gate structure on the second active pattern, the gate structure including a gate insulation pattern and a fourth conductive pattern sequentially stacked in a vertical direction, the fourth conductive pattern including polysilicon doped with the second impurities.

### CROSS-REFERENCE TO RELATED APPLICATION

This application claims priority under 35 U.S.C. § 119 to Korean Patent Application No. 10-2024-0009330 filed on Jan. 22, 2024 in the Korean Intellectual Property Office, the disclosure of which is hereby incorporated by reference in its entirety.

### BACKGROUND

### Technical Field

Example embodiments relate to semiconductor devices, more particularly, DRAM devices.

### Related Art

A DRAM device may include a bit line structure on a cell region and a gate structure on a peripheral circuit region. The bit line structure and the first gate structure may include conductive patterns, respectively. Electrical characteristics of the bit line structure and the first gate structure may vary depending on the material of the conductive patterns.

### SUMMARY

Example embodiments provide semiconductor devices having improved characteristics.

According to an example embodiment, a semiconductor device may include a substrate including a first region and a second region, a first active pattern and a second active pattern on the first and second regions of the substrate, respectively, a bit line structure extending in a horizontal direction substantially parallel to an upper surface of the substrate, the bit line structure including a lower conductive structure having first conductive patterns and second conductive patterns alternately and repeatedly arranged in the horizontal direction, the first conductive patterns containing polysilicon doped with first impurities and second impurities, and the second conductive patterns containing polysilicon doped with third impurities, and an upper conductive structure on the lower conductive structure and including a third conductive pattern, a gate structure on the second active pattern, the gate structure including a gate insulation pattern and a fourth conductive pattern sequentially stacked in a vertical direction substantially perpendicular to the upper surface of the substrate, the fourth conductive pattern including polysilicon doped with the second impurities, a contact plug structure on each of opposite ends of the first active pattern, and a capacitor on the contact plug structure.

According to an example embodiment, a semiconductor device may include a substrate including a first region and a second region, a first active pattern and a second active pattern on the first and second regions of the substrate, respectively, a bit line structure including a lower conductive structure extending in a horizontal direction substantially parallel to an upper surface of the substrate, the lower conductive structure contacting an upper surface of a central portion of the first active pattern, a first barrier pattern on the lower conductive structure, and a third conductive pattern on the first barrier pattern, a gate structure on the second active pattern, the gate structure including a gate insulation pattern, a fourth conductive pattern, a second barrier pattern and a fifth conductive pattern sequentially stacked in a vertical direction substantially perpendicular to the upper surface of the substrate, and an upper surface of the fourth conductive pattern being higher than an upper surface of the lower conductive structure, a contact plug structure on each of opposite ends of the first active pattern, and a capacitor on the contact plug structure.

According to an example embodiment, a semiconductor device may include a substrate including a first region and a second region, a first active pattern and a second active pattern on the first and second regions of the substrate, respectively, a bit line structure including a lower conductive structure extending in a horizontal direction substantially parallel to an upper surface of the substrate, the lower conductive structure having first conductive patterns and second conductive patterns alternately and repeatedly arranged in the horizontal direction, a respective one of the second conductive patterns contacting an upper surface of a central portion of the first active pattern, a first barrier pattern on the lower conductive structure, and a third conductive pattern on the first barrier pattern, a gate structure on the second active pattern, the gate structure including a gate insulation pattern, a second barrier pattern and a fourth conductive pattern sequentially stacked in a vertical direction substantially perpendicular to the upper surface of the substrate, a contact plug structure on each of opposite ends of the first active pattern, and a capacitor on the contact plug structure, and wherein the first barrier pattern and the second conductive pattern contain substantially same materials as the second barrier pattern and the fourth conductive pattern, respectively.

In a semiconductor device according to some example embodiments, the conductive patterns each included in the bit line structure on the cell region and the first gate structure on the peripheral circuit region may have a desirable concentration of impurities. Accordingly, the bit line structure and the first gate structure may have improved electrical characteristics.

### BRIEF DESCRIPTION OF THE DRAWINGS

FIGS. 1 to 3 are a plan view and cross-sectional views illustrating a semiconductor device in accordance with an example embodiment.

FIGS. 4 to 31 are plan views and cross-sectional views illustrating a method of manufacturing a semiconductor device according to an example embodiment.

FIG. 32 is a cross-sectional view illustrating a semiconductor device in accordance with an example embodiment.

FIGS. 33 to 37 are a plan view and cross-sectional views illustrating a method of manufacturing a semiconductor device according to an example embodiment.

### DETAILED DESCRIPTION

The above and other aspects and features of the semiconductor devices and the methods of manufacturing the same in accordance with some example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, two directions among horizontal directions that are substantially parallel to an upper surface of a substrate 100, which may be substantially orthogonal to each other, may be referred as first and second directions D1 and D2, respectively, and a direction among the horizontal directions, which may have an acute angle with respect to each of the first and second directions D1 and D2, may be referred to as a third direction D3. Additionally, a direction substantially perpendicular to the upper surface of the substrate 100 may be referred to as a vertical direction.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

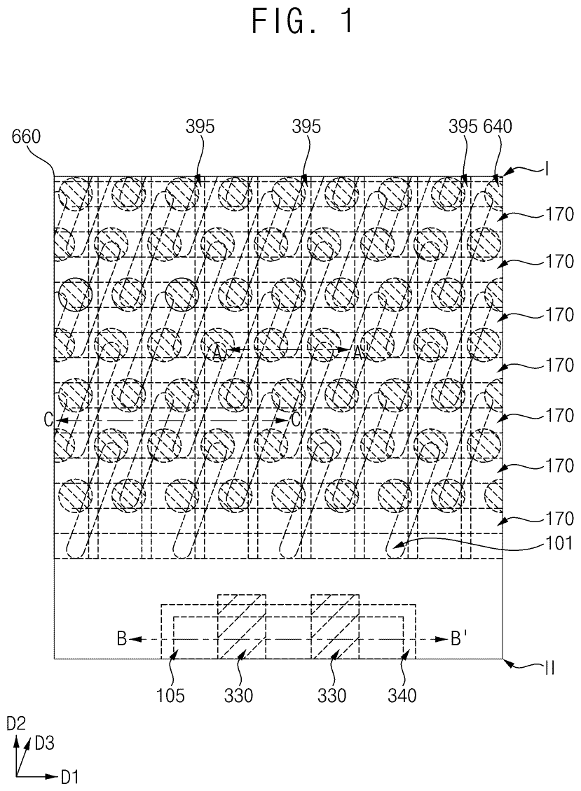

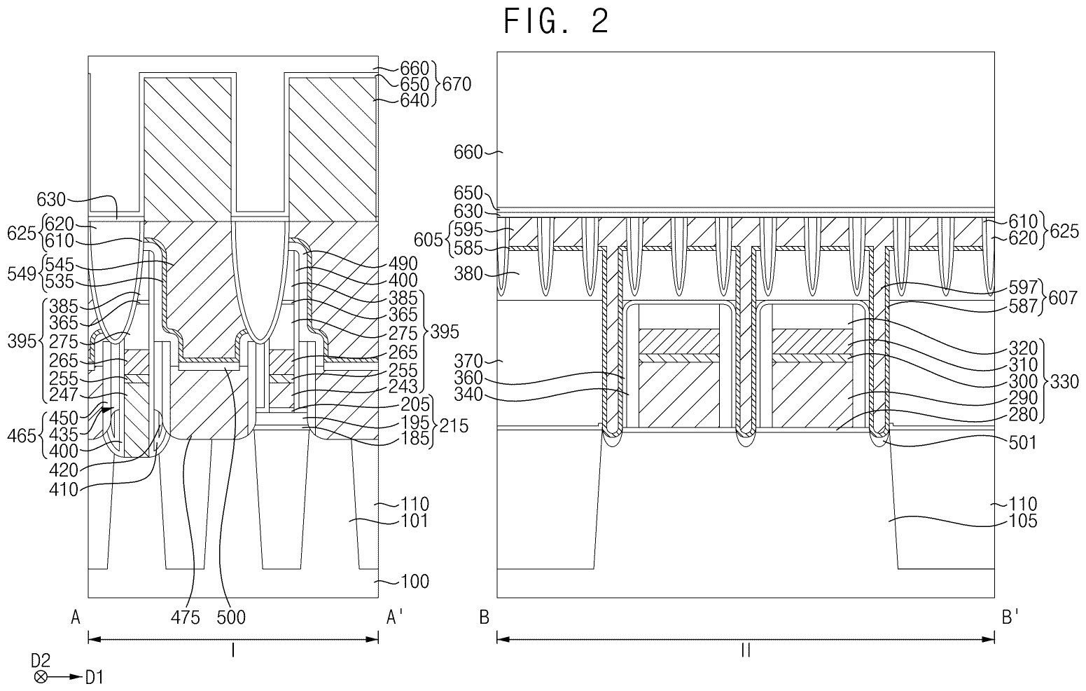

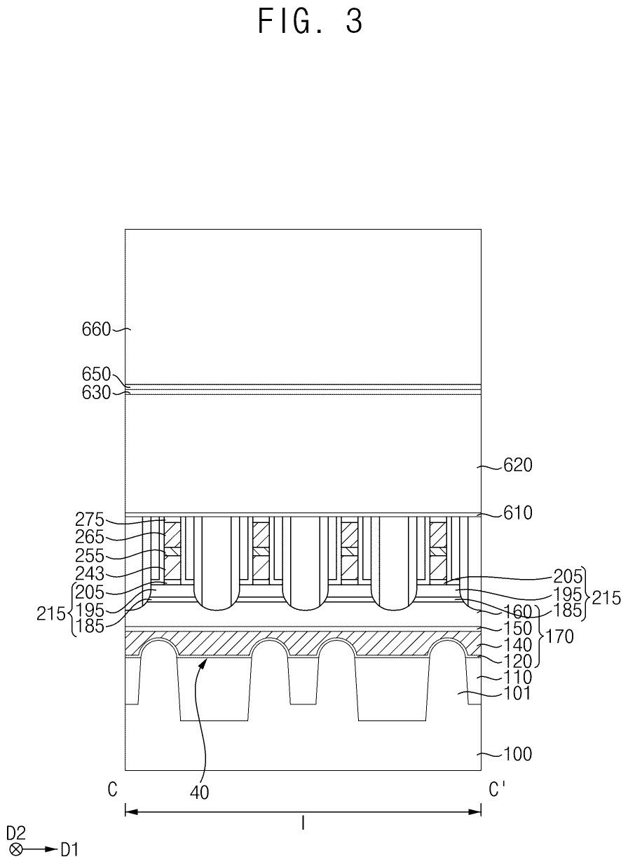

FIG. 1 is a plan view illustrating a semiconductor device in accordance with an example embodiment, FIG. 2 includes cross-sectional views taken along lines A-A′ and B-B′ of FIG. 1, and FIG. 3 is a cross-sectional view taken along line C-C′ of FIG. 1.

Referring to FIGS. 1 to 3, the semiconductor device may include first and second active patterns 101 and 105, first and second gate structures 170 and 330, a bit line structure 395, a contact plug structure, a wiring 605, a second upper contact plug 607 and a capacitor 670 on the substrate 100.

The semiconductor device may further include an isolation pattern 110, a first insulation pattern structure 215, fourth and fifth insulation patterns 410 and 420, a spacer structure 465, a fourth spacer 490, a second ohmic contact pattern 501, a fence pattern 480, a gate spacer 340, a first etch stop layer 360, an insulating interlayer 370, a capping layer 380 and a second insulation pattern structure 625.

The substrate 100 may include silicon, germanium, silicon-germanium, or a III-V group compound semiconductor, such as GaP, GaAs, or GaSb. In some example embodiments, the substrate 100 may be a silicon-on-insulator (SOI) substrate or a germanium-on-insulator (GOI) substrate.

The first region I of the substrate 100 may be a cell region on which memory cells are formed, and the second region II of the substrate 100 surrounding the first region I of the substrate 100 may be a peripheral circuit region on which peripheral circuit patterns for driving the memory cells are formed. FIGS. 1 to 3 show a portion of the first region I and portions of the second region II adjacent to the first region I in the first and second directions D1 and D2, respectively.

The first active pattern 101 may extend in the third direction D3 on the first region I of the substrate 100, and a plurality of first active patterns 101 may be spaced apart from each other in the first and second directions D1 and D2. The second active pattern 105 may be spaced apart from each other in the first and second directions D1 and D2 on the second region II of the substrate 100.

Sidewalls of the first and second active patterns 101 and 105 may be covered by the isolation pattern 110. The first and second active patterns 105 may include substantially the same material as the substrate 100, and the isolation pattern 110 may include an oxide (e.g., silicon oxide).

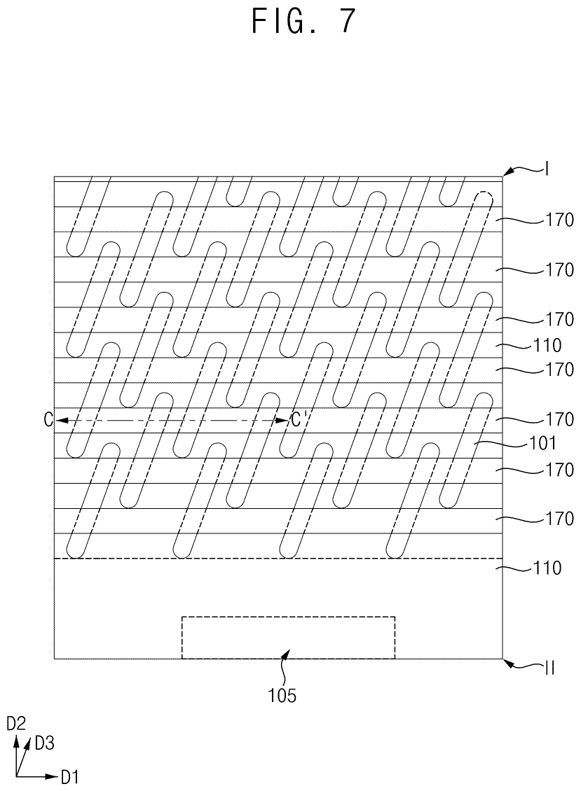

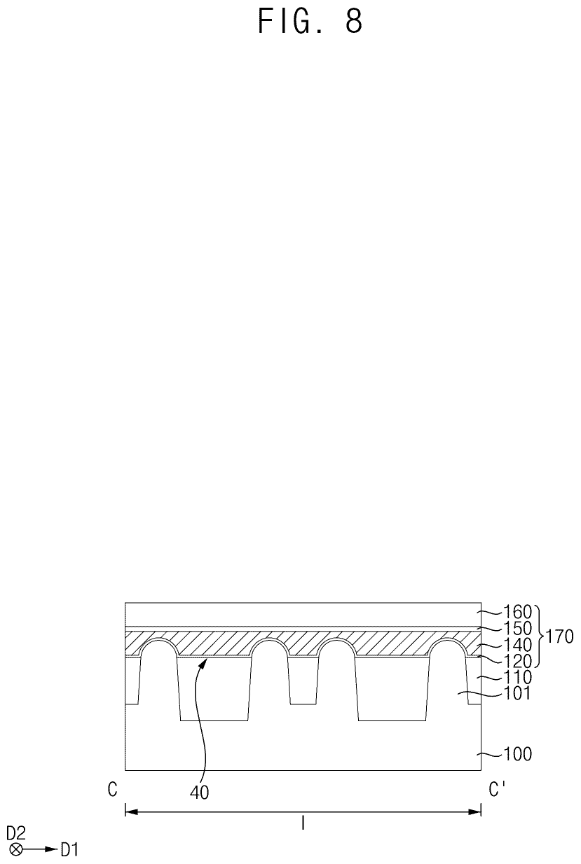

Referring to FIGS. 1 to 3 together with FIGS. 7 and 8, the first gate structure 170 may be formed in a fourth recess 40 extending in the first direction D1 through upper portions of the first active pattern 101 and the isolation pattern 110. The first gate structure 170 may include a first gate insulation pattern 120 on a bottom and a sidewall of the fourth recess 40, a first gate electrode on a portion of the first gate insulation pattern 120 on the bottom and a lower sidewall of the fourth recess 40, and a first gate mask 160 on the first gate electrode. The first gate electrode may include a first conductive pattern 140 and a second conductive pattern 150 sequentially stacked in the vertical direction, and a first barrier pattern (although not illustrated) may be further disposed between the first gate insulation pattern 120 and the first conductive pattern 140.

The first gate insulation pattern 120 may include oxide (e.g., silicon oxide), the first barrier pattern may include metal nitride (e.g., titanium nitride, tantalum nitride), the first conductive pattern 140 may include metal (e.g., tungsten), metal nitride (e.g., titanium nitride and tantalum nitride), metal silicide, polysilicon doped with impurities, etc., and the first gate mask 160 may include insulating nitride (e.g., silicon nitride).

In some example embodiments, the first gate structure 170 may extend in the first direction D1 on the first region I of the substrate 100, and a plurality of gate structures 170 may be spaced apart from each other in the second direction D2.

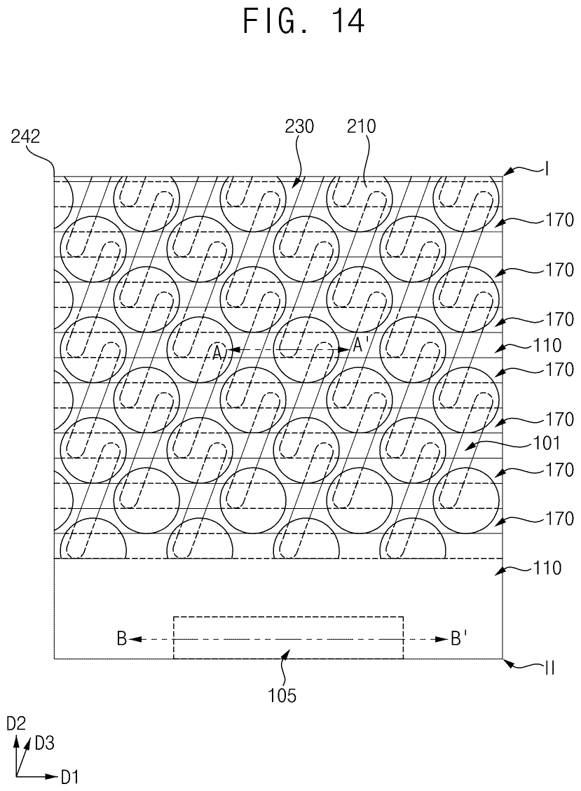

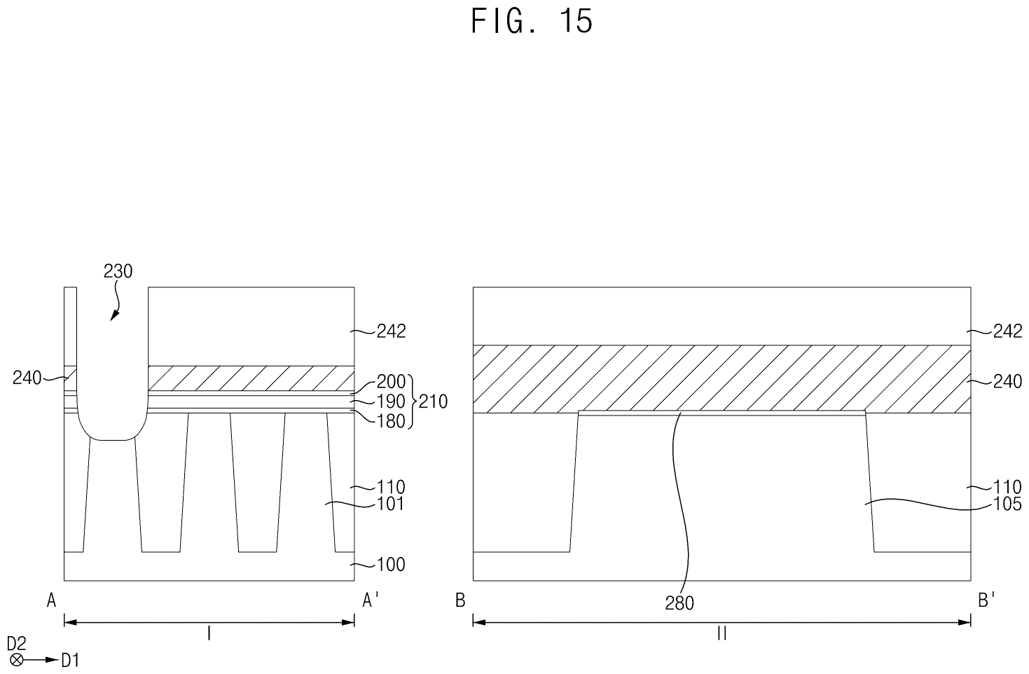

Referring to FIGS. 1 to 3 together with FIGS. 14 and 15, a first opening 230 extending through a first insulation layer structure 210 and exposing upper surfaces of the first active pattern 101, the isolation pattern 110 and the first gate mask 160 of the first gate structure 170 may be formed, and an upper surface of a central portion in the third direction D3 of the first active pattern 101 may be exposed by the first opening 230.

In some example embodiments, an area of a bottom of the first opening 230 may be greater than an area of the upper surface of the first active pattern 101. Thus, the first opening 230 may also expose an upper surface of a portion of the isolation pattern 110 adjacent to the first active pattern 101. Additionally, the first opening 230 may extend through upper portions of the first active pattern 101 and a portion of the isolation pattern 110 adjacent thereto, and thus the bottom of the first opening 230 may be lower than an upper surface of each of opposite edge portions in the third direction D3 of the first active pattern 101.

The bit line structure 395 may include a fifth conductive pattern 243, a sixth conductive pattern 247, a third barrier pattern 255, a seventh conductive pattern 265, a third mask 275, a first etch stop pattern 365 and a capping pattern 385 sequentially stacked in the vertical direction on the first opening 230 or the first insulation pattern structure 215. The fifth and sixth conductive patterns 243 and 247 may collectively form a lower conductive structure, the third barrier pattern 255 and the seventh conductive pattern 265 may collectively form an upper conductive structure, and the third mask 275, the first etch stop pattern 365 and the capping pattern 385 may collectively form an insulation structure.

The lower conductive structure may extend in the second direction D2, the fifth conductive pattern 243 of the lower conductive structure may be formed on the first insulation pattern structure 215 at an outside of the first opening 230, and the sixth conductive pattern 247 may be formed on the first opening 230. The fifth and sixth conductive patterns 243 and 247 may be alternately arranged in the second direction D2 and contact each other.

In some example embodiments, a lower surface of the sixth conductive pattern 247 may be lower than a lower surface of the fifth conductive pattern 243 and contact the upper surface of a central portion of the first active pattern 101.

The fifth and sixth conductive patterns 243 and 247 may include, for example, polysilicon doped with impurities. The impurities may include n-type impurities (e.g., phosphorus (P), arsenic (As), etc.).

In some example embodiments, the fifth conductive pattern 243 may include first impurities and second impurities, and the first and second impurities may be the same or different from each other. Hereinafter, a doping concentration of the impurities of the fifth conductive pattern 243, that is, the sum of a doping concentration of the first impurities and a doping concentration of the second impurities, may be referred to as a first doping concentration.

In some example embodiments, the sixth conductive pattern 247 may include third impurities. Hereinafter, a doping concentration of the third impurities of the sixth conductive pattern 247 may be referred to as a third doping concentration.

In some example embodiments, the third doping concentration of the sixth conductive pattern 247 may be greater than the first doping concentration of the fifth conductive pattern 243.

The third barrier pattern 255 may include metal nitride (e.g., titanium nitride), metal silicon nitride (e.g., titanium silicon nitride), the seventh conductive pattern 265 may include metal (e.g., tungsten), and each of the third mask 275, the first etch stop pattern 365 and the capping pattern 385 may include insulating nitride (e.g., silicon nitride).

In some example embodiments, the bit line structure 395 may extend in the second direction D2 on the first region I of the substrate 100, and a plurality of bit line structures 395 may be spaced apart from each other in the first direction D1.

The fourth and fifth insulation patterns 410 and 420 may be formed in the first opening 230, and may contact a lower sidewall of the bit line structure 395. The fourth insulation pattern 410 may include oxide (e.g., silicon oxide), and the fifth insulation pattern 420 may include insulating nitride (e.g., silicon nitride).

The first insulation pattern structure 215 may be formed on the first active pattern 101 and the isolation pattern 110 under the bit line structure 395, and may include first, second and third insulation patterns 185, 195 and 205 sequentially stacked in the vertical direction. The first and third insulation patterns 185 and 205 may include oxide (e.g., silicon oxide), and the second insulation pattern 195 may include insulating nitride (e.g., silicon nitride).

The spacer structure 465 may include a first spacer 400 covering sidewalls of the bit line structure 395 and the third insulation pattern 205, an air spacer 435 on a lower outer sidewall of the first spacer 400, and a third spacer 450 on an outer sidewall of the air spacer 435, a sidewall of the first insulation pattern structure 215, and upper surfaces of the fourth and fifth insulation patterns 410 and 420.

Each of the first and third spacers 400 and 450 may include insulating nitride (e.g., silicon nitride), and the air spacer 435 may include air.

The fourth spacer 490 may be formed on an outer sidewall of a portion of the first spacer 400 on an upper sidewall of the bit line structure 395, and may cover an upper end of the air spacer 435 and an upper surface of the third spacer 450. The fourth spacer 490 may include insulating nitride (e.g., silicon nitride).

The second gate structure 330 may at least partially overlap the second active pattern 105 in the vertical direction on the second region II of the substrate 100. Accordingly, a plurality of second gate structures 330 may be spaced apart from each other in the first and second directions D1 and D2.

The second gate structure 330 may include a second gate insulation pattern 280, a third conductive pattern 290, a second barrier pattern 300, a fourth conductive pattern 310 and a second gate mask 320 sequentially stacked in the vertical direction, and the third conductive pattern 290, the second barrier pattern 300 and the fourth conductive pattern 310 may collectively form a second gate electrode.

The second gate insulation pattern 280 of the second gate structure 330 may include, for example, silicon oxide (SiO₂), silicon oxynitride (SiON), etc.

The third conductive pattern 290, the second barrier pattern 300, the fourth conductive pattern 310 and the second gate mask 320 of the second gate structure 330 may each include the same material as the fifth conductive pattern 243, the third barrier pattern 255, the seventh conductive pattern 265 and the third mask 275 of the bit line structure 395, respectively.

However, unlike the fifth conductive pattern 243 of the bit line structure 395 that includes polysilicon doped with the first and second impurities, the third conductive pattern 290 of the second gate structure 330 may include polysilicon doped only with the second impurities among the first and second impurities. That is, the third conductive pattern 290 of the second gate structure 330 may not include the first impurities.

In some example embodiments, the first doping concentration of the first and second impurities included in the fifth conductive pattern 243 may be greater than a second doping concentration of the second impurities included in the third conductive pattern 290. Accordingly, among the first doping concentration of the fifth conductive pattern 243 of the bit line structure 395, the second doping concentration of the third conductive pattern 290 of the second gate structure 330 and the third doping concentration of the sixth conductive pattern 247 of the bit line structure 395, the first doping concentration is the greatest and the third doping concentration is the smallest.

In some example embodiments, the first doping concentration may be about 1.4 times to about 5 times the second doping concentration.

In some example embodiments, an upper surface of the third conductive pattern 290 of the second gate structure 330 may be higher than an upper surface of the lower conductive structure of the bit line structure 395.

The gate spacer 340 may cover a sidewall of the second gate structure 330. The gate spacer 340 may include oxide (e.g., silicon oxide) or insulating nitride (e.g., silicon nitride).

However, the structure of the spacer structure 465 and the gate spacer 340 may not be limited thereto, and each of the spacer structure 465 and the gate spacer 340 may include a single spacer or more than two spacers sequentially stacked.

The first etch stop layer 360 may be formed on the second region II of the substrate 100 to cover an upper surface of the second gate structure 330, an outer sidewall of the gate spacer 340 and an upper surface of the isolation pattern 110. The first etch stop layer 360 may include the same material as the first etch stop pattern 365.

The insulating interlayer 370 may be formed on the first etch stop layer 360 on the second region II of the substrate 100 to a sufficient height, and an uppermost surface of the insulating interlayer 370 may be substantially coplanar with an upper surface of a portion of the first etch stop layer 360 on the second gate structure 330. The insulating interlayer 370 may include oxide (e.g., silicon oxide), and the capping layer 380 may include nitride (e.g., silicon nitride).

The capping layer 380 may be disposed on the first etch stop layer 360 and the insulating interlayer 370 on the second region II of the substrate 100. The capping layer 380 may include insulating nitride (e.g., silicon nitride).

The contact plug structure may include a lower contact plug 475, a first ohmic contact pattern 500 and a first upper contact plug 549 sequentially stacked in the vertical direction on the first active pattern 101 and the isolation pattern 110 on the first region I of the substrate.

The lower contact plug 475 may contact the upper surface of the edge portion in the third direction D3 of the first active pattern 101. In some example embodiments, a plurality of lower contact plugs 475 may be spaced apart from each other in the second direction D2, and the fence pattern 480 may be formed between neighboring ones of the lower contact plugs 475 in the second direction D2. The fence pattern 480 may include an insulating nitride (e.g., silicon nitride).

The lower contact plug 475 may include, for example, doped polysilicon, the first ohmic contact pattern 500 may include metal silicide (e.g., titanium silicide, cobalt silicide, nickel silicide, etc.).

The first upper contact plug 549 may include a first metal pattern 545 and a fourth barrier pattern 535 covering a lower surface of the first metal pattern 545. The first metal pattern 545 may include metal (e.g., tungsten), and the fourth barrier pattern 535 may include metal nitride (e.g., titanium nitride).

In some example embodiments, a plurality of first upper contact plugs 549 may be spaced apart from each other in the first and second directions D1 and D2, and may be arranged in a honeycomb pattern or a lattice pattern in a plan view. Each of the first upper contact plugs 549 may have a shape of, for example, a circle, an ellipse, or a polygon, in a plan view.

The wiring 605 may include a second metal pattern 595 and a fifth barrier pattern 585 covering a lower surface of the second metal pattern 595. In some example embodiments, a plurality of wirings 605 may be spaced apart from each other in the first and second directions D1 and D2.

The second ohmic contact pattern 501 may be formed on an upper surface of the second active pattern 105 adjacent to the second gate structure 330.

The second upper contact plug 607 may include a third metal pattern 597 and a sixth barrier pattern 587 covering a lower surface of the third metal pattern 597. The second upper contact plug 607 may extend through the capping layer 380, the insulating interlayer 370 and the second gate insulation pattern 280 to contact an upper surface of the second ohmic contact pattern 501.

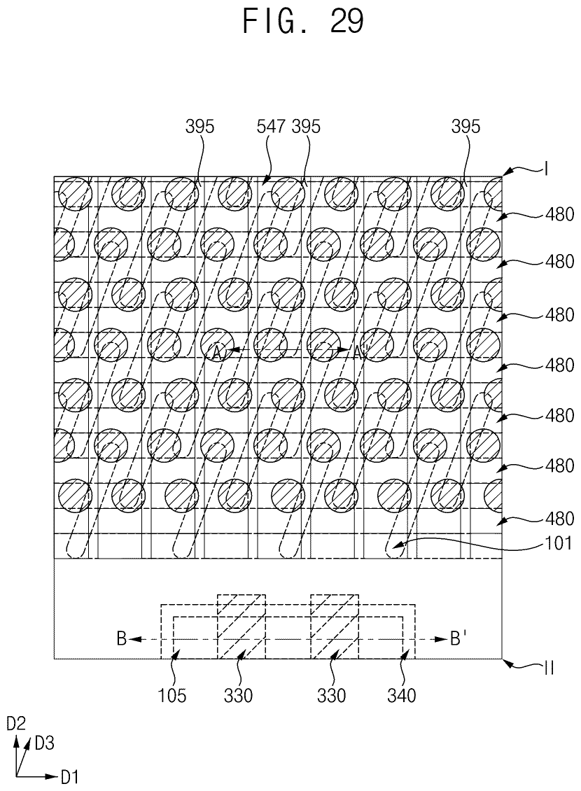

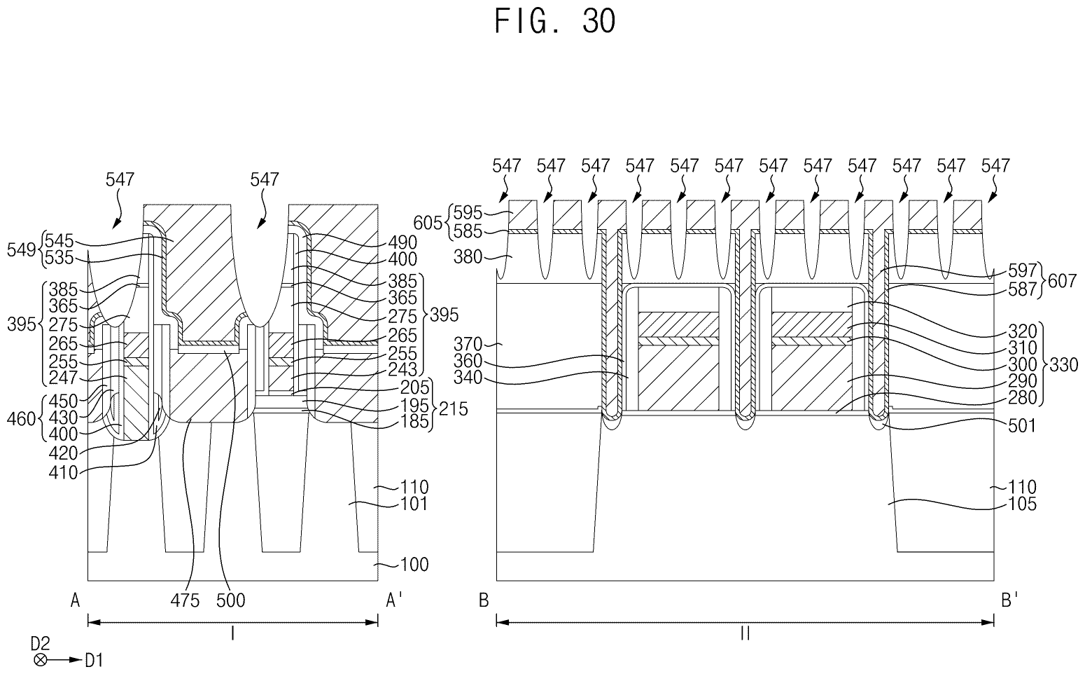

Each of the second and third metal patterns 595 and 597 may include metal (e.g., tungsten), and each of the fifth and sixth barrier patterns 585 and 587 may include metal nitride (e.g., titanium nitride). Referring to FIGS. 1 to 3 together with FIGS. 29 and 30, the second insulation pattern structure 625 may include a sixth insulation pattern 610 on an inner wall of a seventh opening 547, which may extend through the first upper contact plug 549, a portion of the insulation structure of the bit line structure 395 and portions of the first, third and fourth spacers 400, 450 and 490 and surround the first upper contact plug 549 in a plan view, and a seventh insulation pattern 620 disposed on the sixth insulation pattern 610 and filling a remaining portion of the seventh opening 547. The upper end of the air spacer 435 may be closed by the sixth insulation pattern 610.

The sixth and seventh insulation patterns 610 and 620 may include insulating nitride (e.g., silicon nitride).

The second etch stop layer 630 may be formed on the sixth and seventh insulation patterns 610 and 620, the first upper contact plug 549 and the fence pattern 480. The second etch stop layer 630 may include insulating nitride (e.g., silicon boronitride, silicon nitride, etc.).

The capacitor 670 may include a lower electrode 640, a dielectric layer 650 and an upper electrode 660 that are sequentially stacked, and the lower electrode 640 may extend through the second etch stop layer 630 to contact an upper surface of the first upper contact plug 549. In some example embodiments, the lower electrode 640 may have a shape of, for example, a pillar or a cylinder.

The lower electrode 640 may include, for example, metal, metal nitride, metal silicide, polysilicon doped with impurities, the dielectric layer 650 may include, for example, metal oxide, and the upper electrode 660 may include, for example, metal, metal nitride, metal silicide, silicon-germanium (SiGe) doped with impurities.

In the semiconductor device, the first doping concentration of the fifth conductive pattern 243 of the bit line structure 395 may be greater than the second doping concentration of the third conductive pattern 290 of the second gate structure 330. Accordingly, resistance of the bit line structure 395 may be kept low while the threshold voltage of the second gate structure 330 may be prevented from increasing.

Additionally, an upper surface of the lower conductive structure of the bit line structure 395 may be lower than an upper surface of the third conductive pattern 290 of the second gate structure 330. Accordingly, the aspect ratio of the bit line structure 395 including the lower conductive structure may be reduced, thereby reducing the difficulty of manufacturing the semiconductor device. Also, the parasitic capacitance between the bit line structure 395 including the lower conductive structure and the contact plug structure may be reduced.

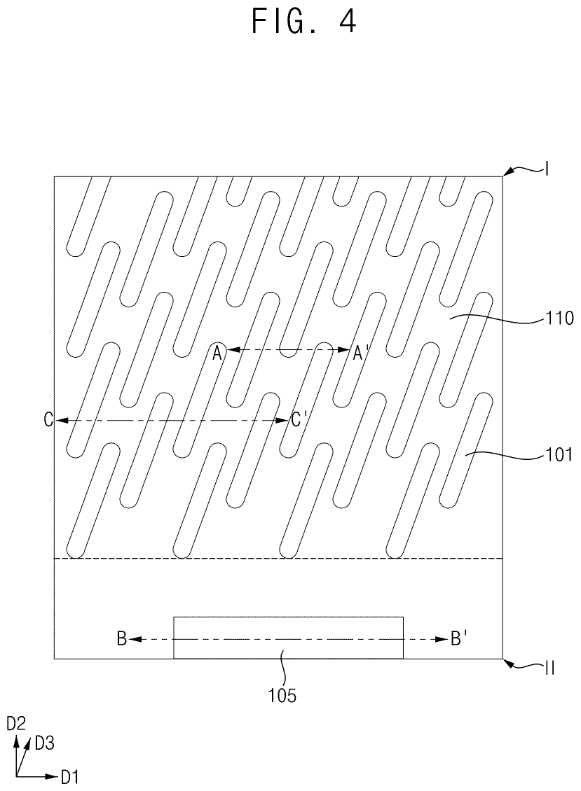

FIGS. 4 to 31 are plan views and cross-sectional views illustrating a method of manufacturing a semiconductor device according to an example embodiment.

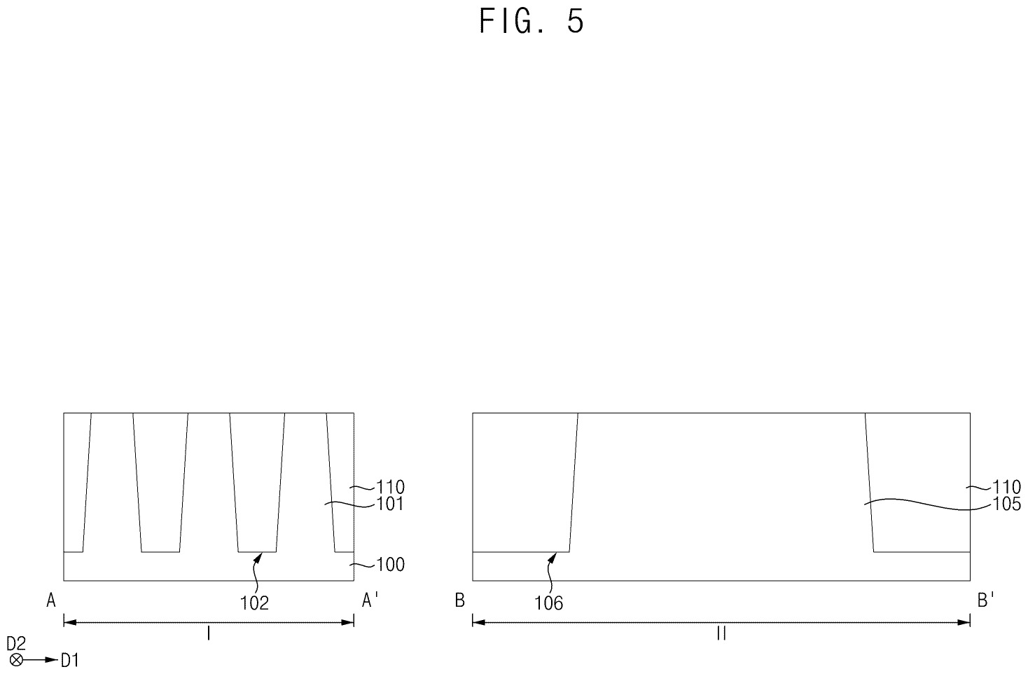

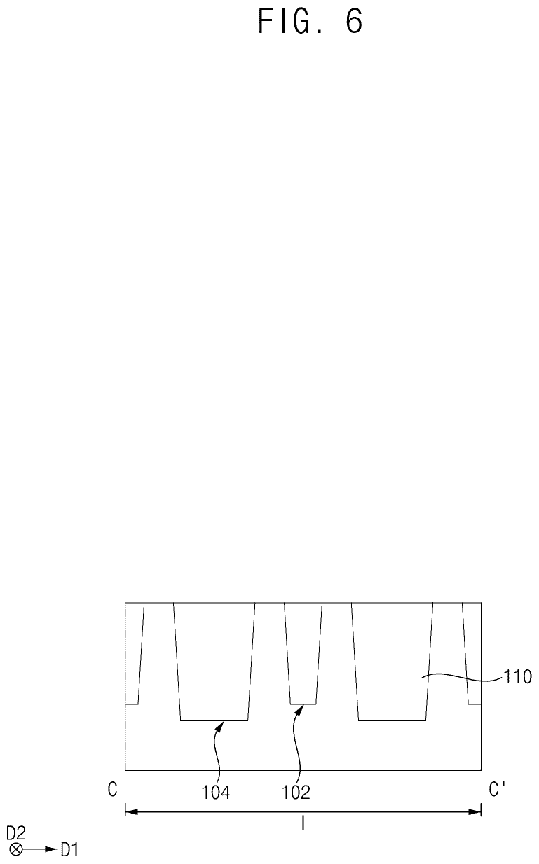

Specifically, FIGS. 4, 7, 9, 11, 14, 18, 21, 25 and 29 are the plan views, FIGS. 5, 10, 12-13, 15-17, 19-20, 22-24, 26-28, and 30-31 include cross-sectional views taken along lines A-A′ and B-B′, respectively, of corresponding plan views, and FIGS. 6 and 8 are cross-sectional views taken along lines C-C′, respectively, of corresponding plan views.

Referring to FIGS. 4 to 6, first and second active patterns 101 and 105 may be formed on the substrate 100 including first and second regions I and II.

The first and second active patterns 101 and 105 may be formed by removing an upper portion of the substrate 100 to form a recess structure.

The recess structure may include first, second and third recesses 102, 104 and 106. The first recess 102 may be formed between ones of the first active patterns 101 spaced apart from each other by a relatively small distance, the second recess 104 may be formed between ones of the first active patterns 101 spaced apart from each other by a relatively large distance, and the third recess 106 may be formed on the second region II of the substrate 100 or between the first and second regions I and II of the substrate 100.

In some example embodiments, the third recess 106 may have a width and/or a depth greater than a width and/or a depth of the second recess 104, and the second recess 104 may have a width and/or a depth greater than a width and/or a depth of the first recess 102.

An isolation pattern 110 may be formed to cover sidewalls of the first and second active patterns 101 and 105. Accordingly, the first and second active patterns 101 and 105 whose sidewalls are covered by the isolation pattern 110 may be defined.

Referring to FIGS. 7 and 8, an etching process may be performed on the first active pattern 101 and the isolation pattern 110 on the first region I of the substrate 100 to form a fourth recess 40 extending in the first direction D1.

In some example embodiments, during the etching process, the first active pattern 101 including a semiconductor material may be less etched than the isolation pattern 110 including an insulating material due to the etching selectivity. Thus, the fourth recess 40 may have a concave upper surface on an upper surface of the first active pattern 101.

A first gate insulation layer and a first conductive layer may be sequentially stacked on an inner wall of the fourth recess 40 and upper surfaces of the first and second active patterns 101 and 105 and the isolation pattern 110, the first gate insulation layer and the first conductive layer may be planarized until the upper surfaces of the first and second active patterns 101 and 105 and the isolation pattern 110 are exposed, and an upper portion of the first conductive layer may be removed by, for example, an etch back process.

The planarization process may include a chemical mechanical polishing (CMP) process and/or an etch back process.

By the planarization process, a first gate insulation pattern 120 may be formed on the inner wall of the fourth recess 40, and by the etch back process, a first conductive pattern 140 may be formed on the first gate insulation pattern 120 to fill a lower portion of the fourth recess 40.

A second conductive pattern 150 may be formed on the first conductive pattern 140, a first gate mask layer may be formed on the second conductive pattern 150, the first and second active patterns 101 and 105 and the isolation pattern 110 to fill the fourth recess 40, and the first gate mask layer may be planarized until the upper surfaces of the first and second active patterns 101 and 105 and the isolation pattern 110 are exposed, so that a first gate mask 160 may be formed to fill an upper portion of the fourth recess 40. The first conductive pattern 140 and the second conductive pattern 150 may collectively form a gate electrode, and a first barrier pattern (although not illustrated) may be further formed between the first gate insulation pattern 120 and the first conductive pattern 140.

The first gate insulation pattern 120, the first barrier pattern, the first conductive pattern 140, the second conductive pattern 150 and the first gate mask 160 in the fourth recess 40 may collectively form a first gate structure 170.

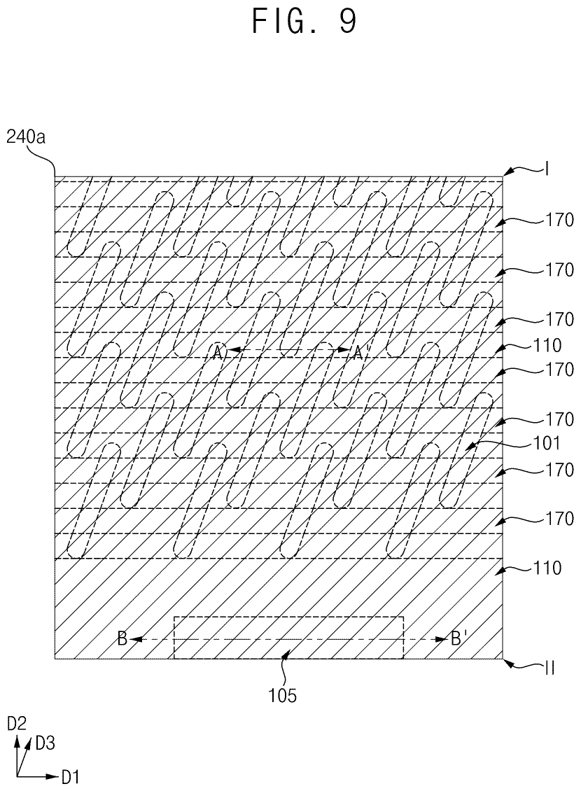

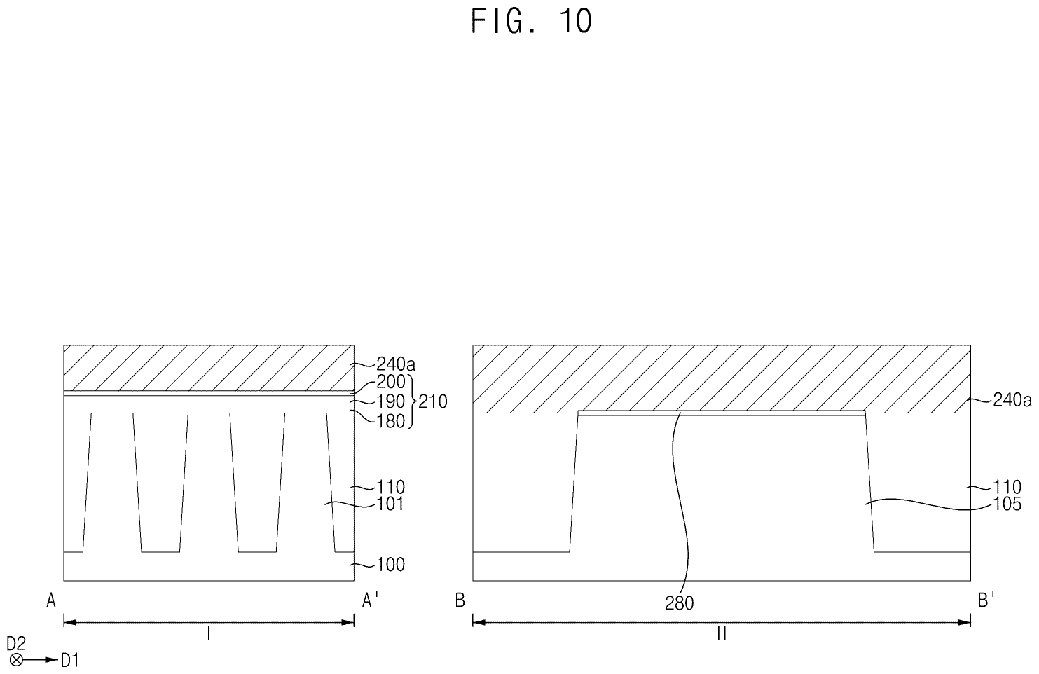

Referring to FIGS. 9 and 10, a first insulation layer structure 210 may be formed on the first and second regions I and II of the substrate 100, and a portion of the first insulation layer structure 210 on the second region II of the substrate 100 may be removed.

The first insulation layer structure 210 may include first to third insulation layers 180, 190 and 200 sequentially stacked.

A second gate insulation pattern 280 may be formed on the upper surface of the second active pattern 105 on the second region II of the substrate 100. For example, a thermal oxidation process may be performed on the second active pattern 105 on the second region II of the substrate 100 to form the second gate insulation pattern 280.

A preliminary third conductive layer 240a may be formed on the third insulation layer 200 on the first region I of the substrate 100, and the isolation pattern 110 and the second gate insulation pattern 280 on the second region II of the substrate 100. The preliminary third conductive layer 240a may include, for example, undoped polysilicon.

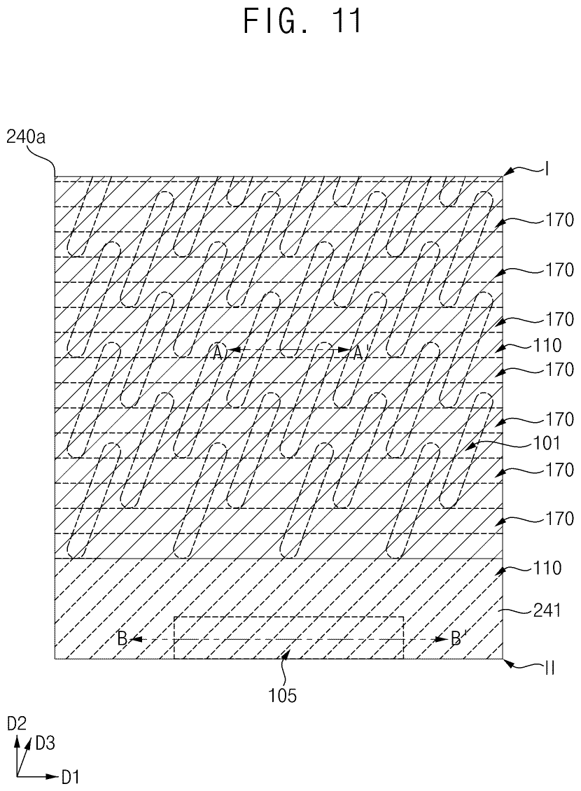

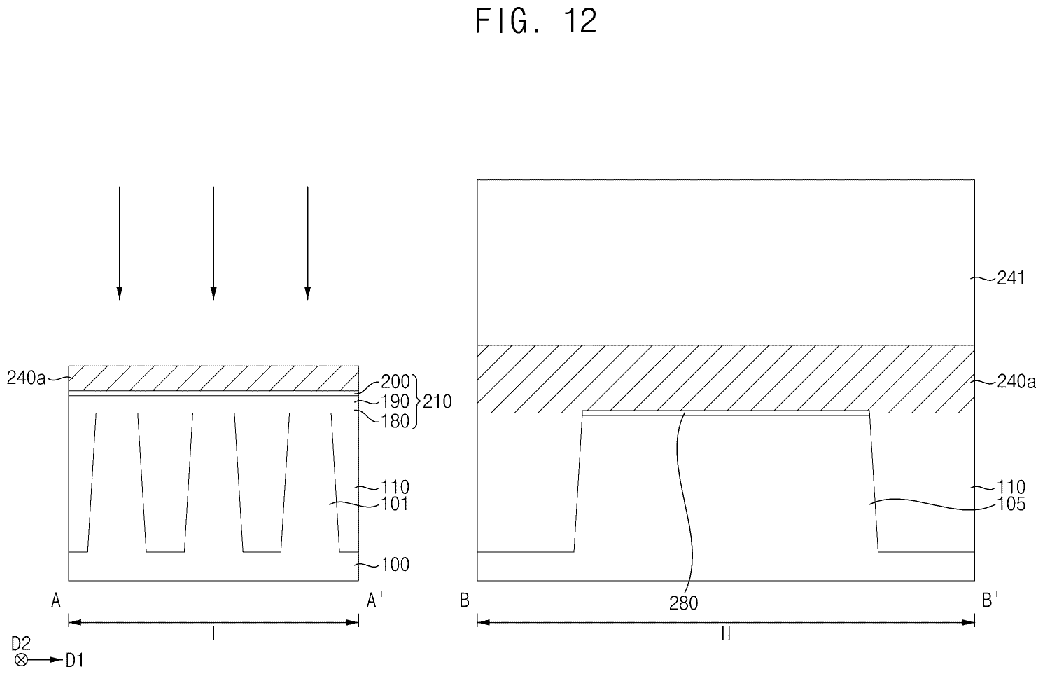

Referring to FIGS. 11 and 12, a first mask 241 may be formed to cover a portion of the preliminary third conductive layer 240a on the second region II of the substrate 100, and accordingly, the upper surface of the preliminary third conductive layer 240a on the first region I of the substrate 100 may be exposed.

An upper portion of the exposed preliminary third conductive layer 240a may be removed by, for example, performing an etch-back process, and thus, the upper surface of the preliminary third conductive layer 240a on the first region I of the substrate 100 may be lower than the upper surface of the preliminary third conductive film 240a on the second region II of the substrate 100.

A first doping process may be performed on the exposed preliminary third conductive layer 240a to dope the preliminary third conductive layer 240a with first impurities. The first impurities may include n-type impurities, for example, phosphorus (P), arsenic (As), etc. In some example embodiments, the first doping process may be performed by, for example, an ion implantation (IIP) process, a gas phase doping (GPD) process, etc.

In some example embodiments, the etch back process may be performed after performing the first doping process.

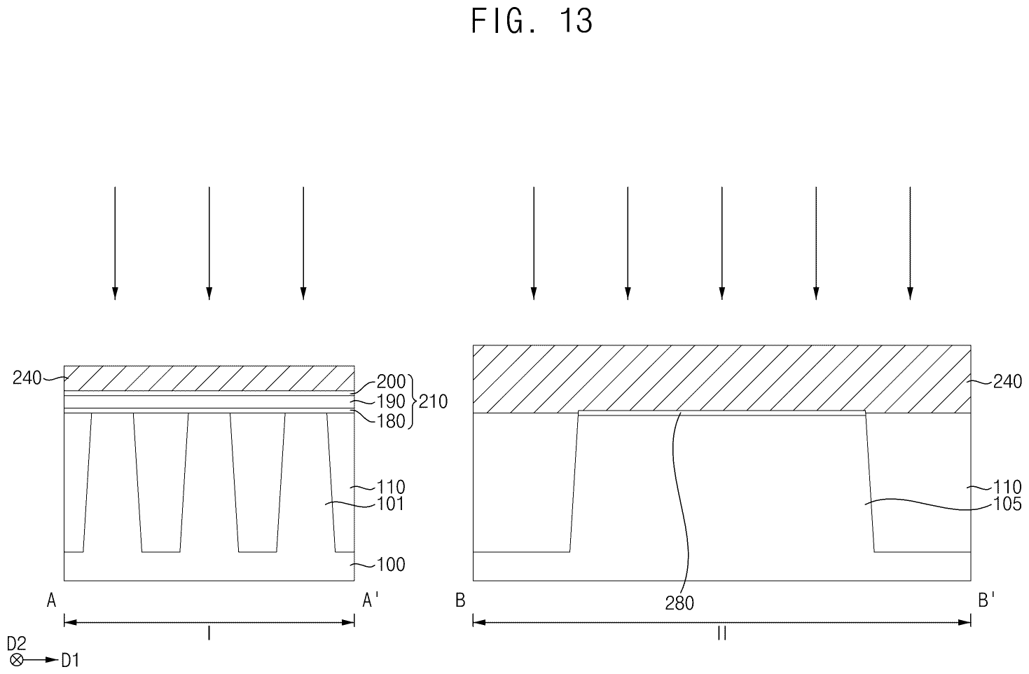

Referring to FIG. 13, after removing the first mask 241, a second doping process may be performed on the of the preliminary third conductive layer 240a to additionally dope the preliminary third conductive layer 240a with second impurities. Accordingly, the preliminary third conductive layer 240a may be converted into the third conductive layer 240.

The second impurities may include, n-type impurities, for example, phosphorus (P), arsenic (As), etc. In some example embodiments, the second impurities may be the same as or different from the first impurities.

A first portion of the third conductive layer 240 on the first region I of the substrate 100 may further include the first impurities than a second portion of the third conductive layer 240 on the second region II of the substrate 100 by the first doping process. Accordingly, a doping concentration of the first portion of the third conductive layer 240 on the first region I of the substrate 100, that is, concentration of the first and second impurities of the first portion of the third conductive layer 240, may be greater than a doping concentration of the second portion of the third conductive layer 240 on the second region II of the substrate 100, that is, concentration of the second impurities of the second portion of the third conductive layer 240.

In some example embodiments, the second doping process may be performed by, for example, an ion implantation (IIP) process, a gas phase doping (GPD) process, etc.

Referring to FIGS. 14 and 15, a second mask 242 may be formed on the third conductive layer 240. The third conductive layer 240, the first insulation layer structure 210, the first active pattern 101, the isolation pattern 110 and the first gate mask 160 of the first gate structure 170 may be etched by an etching process using the second mask 242 as an etching mask to form a first opening 230.

In some example embodiments, the etched first insulation layer structure 210 may have a shape of a circle or an ellipse in a plan view, and a plurality of first insulation layer structures 210 may be spaced apart from each other in the first and second directions D1 and D2 on the first region I of the substrate 100. The first insulation layer structures 210 may overlap the end portions in the third direction D3 of the first active patterns 101, respectively, in a vertical direction substantially perpendicular to the upper surface of the substrate 100.

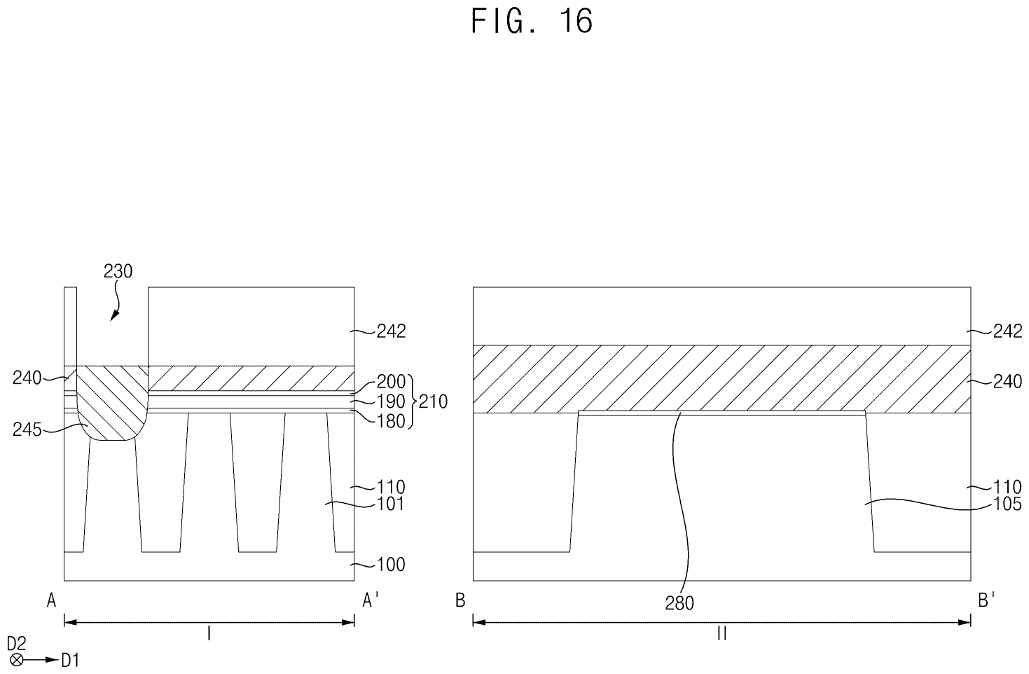

Referring to FIG. 16, a fourth conductive layer 245 may be formed to a sufficient height within the first opening 230, and an etch-back process may be performed on an upper portion of the fourth conductive layer 245.

In some example embodiments, an upper surface of the fourth conductive layer 245 may be substantially coplanar with the upper surface of the third conductive layer 240.

In some example embodiments, the fourth conductive layer 245 may be formed by a deposition process using a source gas of third impurities and a source gas of silicon. Accordingly, the fourth conductive layer 245 may include polysilicon doped with the third impurities. The third impurities may include n-type impurities, for example, phosphorus (P), arsenic (As), etc.

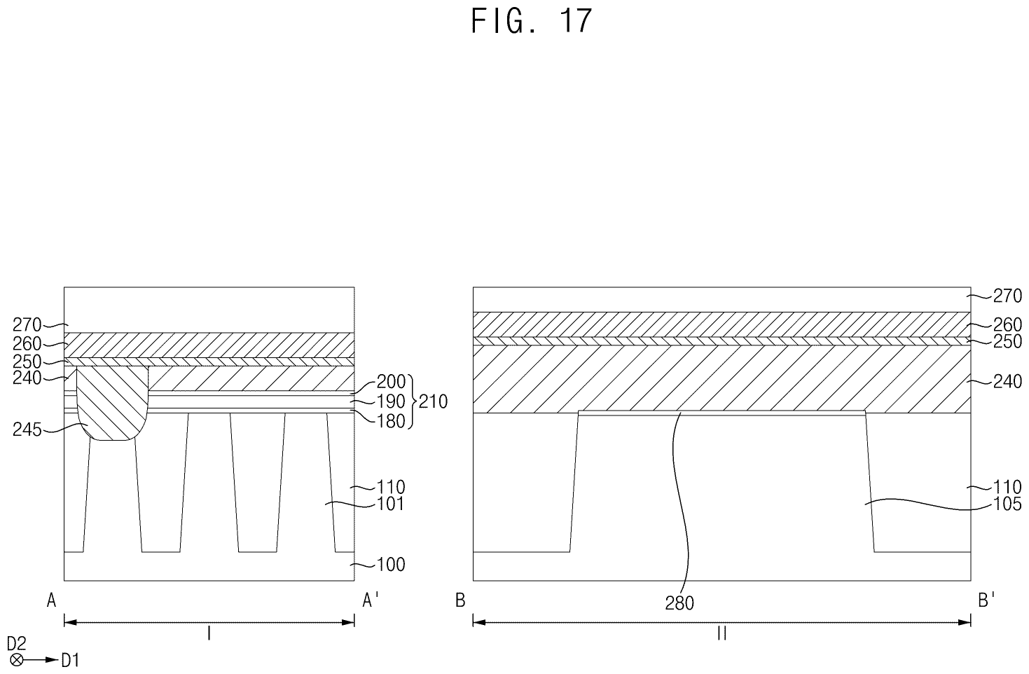

Referring to FIG. 17, the second mask 242 may be removed, and a first barrier layer 250, a fifth conductive layer 260 and a third mask layer 270 may be sequentially stacked on the third and fourth conductive layers 240 and 245 on the first and second regions I and II of the substrate 100.

The third and fourth conductive layers 240 and 245 and the fifth conductive layer 260 may collectively form a conductive structure layer.

In some example embodiments, an upper surface of a portion of the third mask layer 270 on the first region I of the substrate 100 and an upper surface of a portion of the third mask layer 270 on the second region II of the substrate 100 may be substantially coplanar to each other.

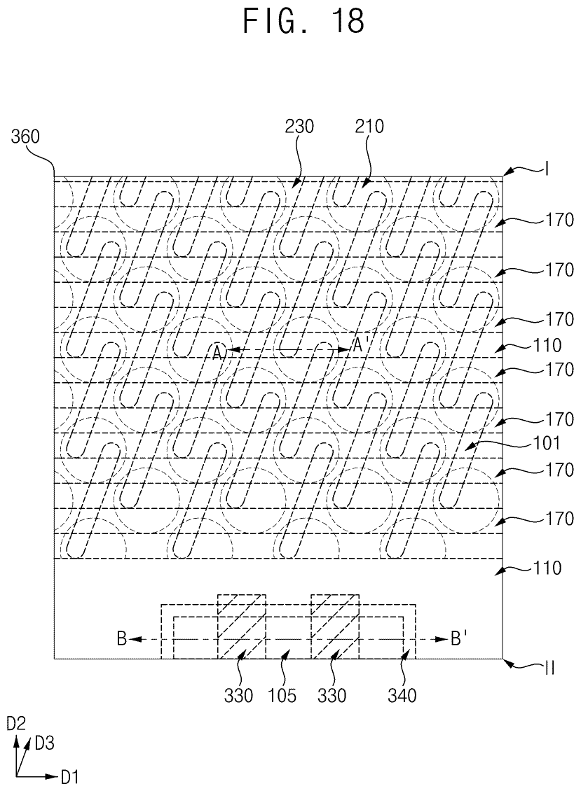

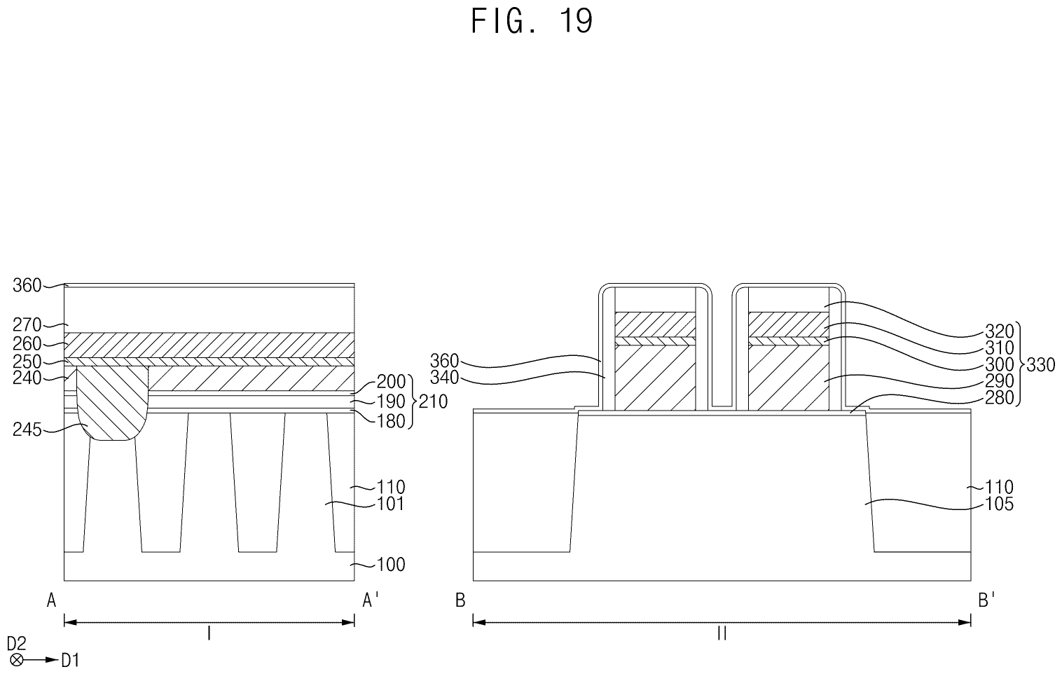

Referring to FIGS. 18 and 19, the conductive structure layer may be patterned to form a second gate structure 330 on the second region II of the substrate 100.

The second gate structure 330 may include a second gate insulation pattern 280, a third conductive pattern 290, a second barrier pattern 300, a fourth conductive pattern 310 and a second gate mask 320 sequentially stacked in the vertical direction, and the third conductive pattern 290, the second barrier pattern 300 and the fourth conductive pattern 310 may collectively form a second gate electrode.

The second gate structure 330 may at least partially overlap the second active pattern 105 in the vertical direction on the second region II of the substrate 100.

A gate spacer 340 may be formed on a sidewall of the second gate structure 330. The gate spacer 340 may be formed by forming a gate spacer layer on the substrate 100 on which the second gate structure 330 is formed, and anisotropically etching the gate spacer layer.

The first etch stop layer 360 may be conformally formed on the substrate 100 on which the conductive structure layer, the second gate structure 330, the gate spacer 340, and the isolation pattern 110 are formed.

In some example embodiments, a plurality of second gate structures 330 may be spaced apart from each other in the first and second directions D1 and D2.

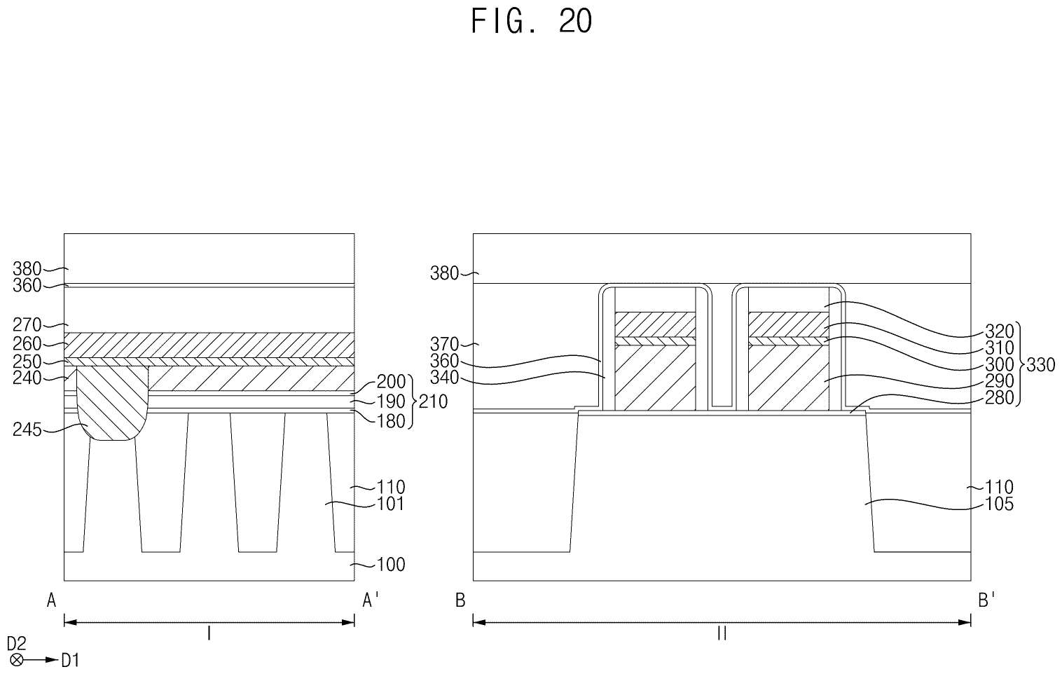

Referring to FIG. 20, an insulating interlayer 370 may be formed on the first etch stop layer 360 to a sufficient height, the insulating interlayer 370 may be planarized until an upper surface of the second gate structure 330 and an upper surface of a portion of the first etch stop layer 360 on the conductive structure layer are exposed, and a capping layer 380 may be formed on the insulating interlayer 370 and the first etch stop layer 360.

Accordingly, the insulating interlayer 370 may fill a space between the gate spacers 340 on the sidewalls of the second gate structures 330.

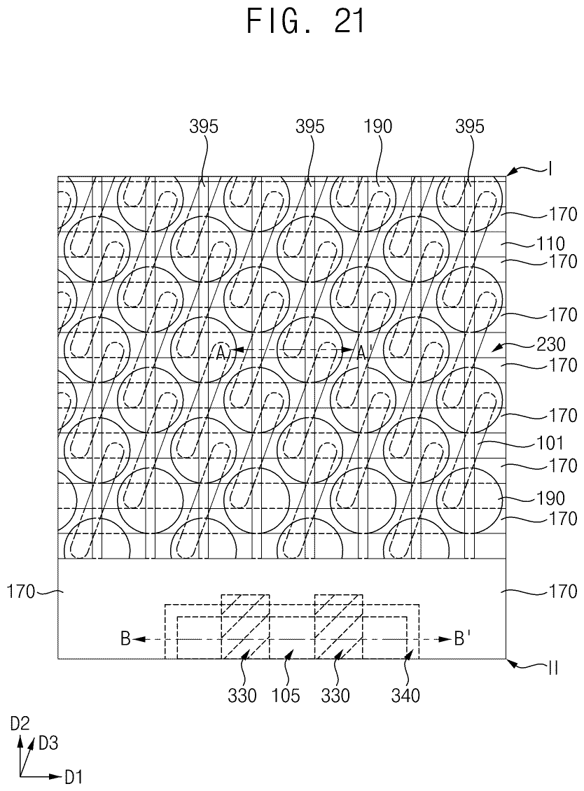

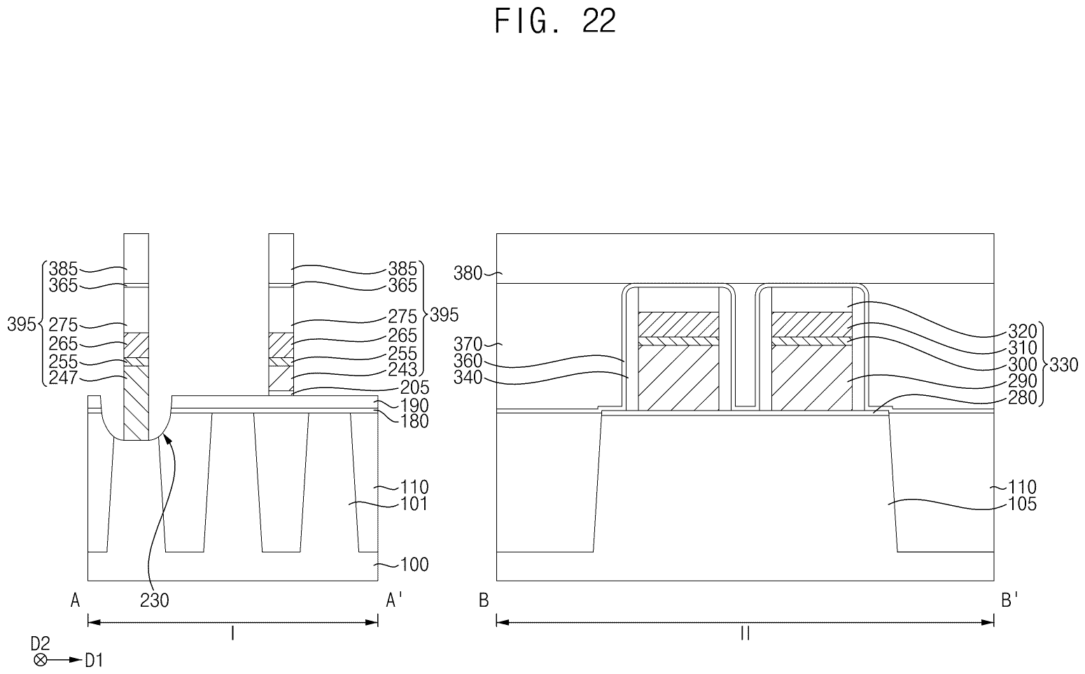

Referring to FIGS. 21 and 22, a portion of the capping layer 380 on the first region I of the substrate 100 may be etched to form a capping pattern 385, and the first etch stop layer 360, the third mask layer 270, the fifth conductive layer 260, the first barrier layer 250, the fourth conductive layer 245 and the third conductive layer 240 may be sequentially etched using the capping pattern 385 as an etching mask.

In some example embodiments, the capping pattern 385 may extend in the second direction D2 on the first region I of the substrate 100, and a plurality of capping patterns 385 may be formed to be spaced apart from each other in the first direction D1. The capping layer 380 may remain on the second region II of the substrate 100.

By the etching process, on the first region I of the substrate 100, a sixth conductive pattern 247, a third barrier pattern 255, a seventh conductive pattern 265, a third mask 275, a first etch stop pattern 365 and the capping pattern 385 may be sequentially stacked on the first opening 230, and a third insulation pattern 205, the fifth conductive pattern 243, the third barrier pattern 255, the seventh conductive pattern 265, the third mask 275, the first etch stop pattern 365 and the capping pattern 385 may be sequentially stacked on the second insulation layer 190 of the first insulation layer structure 210 at an outside of the first opening 230.

The fifth and sixth conductive pattern 243 and 247 may collectively form a lower conductive structure, the third barrier pattern 255 and the seventh conductive pattern 265 may collectively form an upper conductive structure, and the third mask 275, the first etch stop pattern 365 and the capping pattern 385 may collectively form an insulation structure. Hereinafter, the lower conductive structure, the upper conductive structure and the insulation structure may collectively form a bit line structure 395.

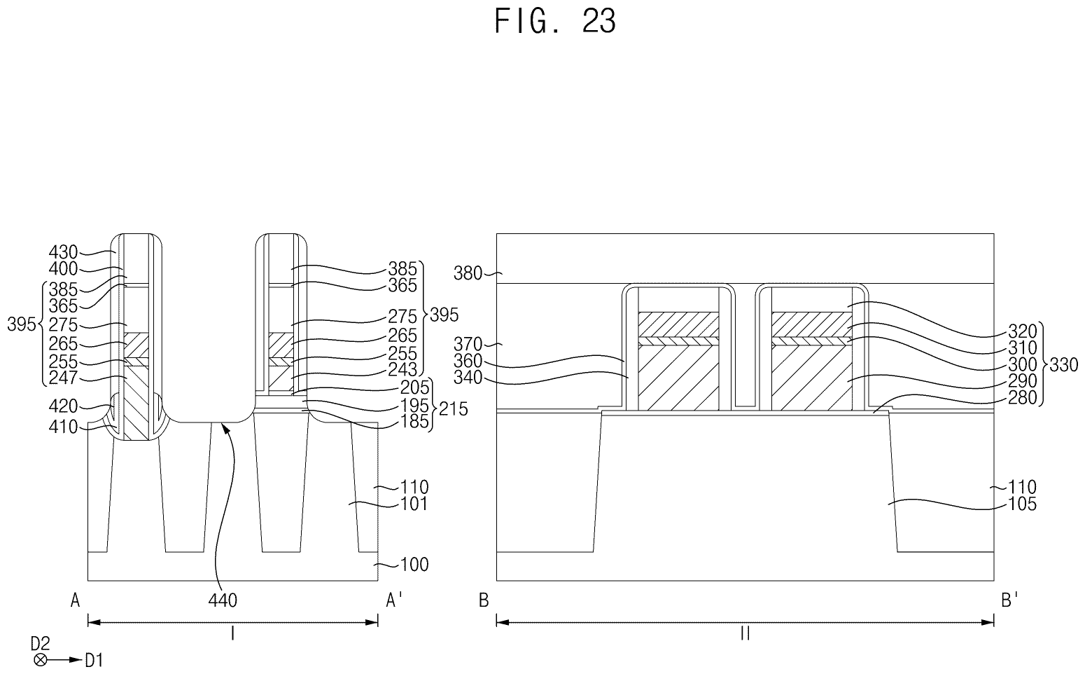

Referring to FIG. 23, a first spacer layer may be formed on the substrate 100 on which the bit line structure 395 and the capping layer 380 are formed, and fourth and fifth insulating layers may be sequentially formed on the first spacer layer.

The first spacer layer may also cover a sidewall of the third insulation pattern 205 under the bit line structure 395 on the second insulating layer 190, and the fifth insulating layer may fill a remaining portion of the first opening 230.

The fourth and fifth insulating layers may be etched by an etching process. In some example embodiments, the etching process may be a wet etching process using, for example, phosphoric acid (H₂PO₃), SC1, and hydrofluoric acid (HF) as an etchant, and portions of the fourth and fifth insulating layers except for portions thereof in the first opening 230 may be removed. Accordingly, most portion of a surface of the first spacer layer, that is, all portions of the surface of the first spacer layer except for a portion of the surface thereof in the first opening 230 may be exposed, and the fourth and fifth insulating layers remaining in the first opening 230 may form fourth and fifth insulation patterns 410 and 420, respectively.

A second spacer layer may be formed on the exposed surface of the first spacer layer and the fourth and fifth insulation patterns 410 and 420 in the first opening 230. The second spacer layer may be anisotropically etched to form a second spacer 430 covering a sidewall of the bit line structure 395 on the surface of the first spacer layer and on the fourth and fifth insulation patterns 410 and 420.

A dry etching process may be performed using the capping pattern 385 and the second spacer 430 as an etch mask to form a second opening 440 exposing an upper surface of the first active pattern 101, and upper surfaces of the isolation pattern 110 the first gate mask 160 may also be exposed by the second opening 440.

By the dry etching process, portions of the first spacer layer on upper surfaces of the capping layer 380, the capping pattern 385 and the second insulating layer 190 may be removed, and thus a first spacer 400 may be formed on the sidewall of the bit line structure 395.

By the dry etching process, the first and second insulating layers 180 and 190 may be partially removed to remain as first and second insulation patterns 185 and 195, respectively, under the bit line structure 395. The first to third insulation patterns 185, 195 and 205 sequentially stacked under the bit line structure 395 may form a first insulation pattern structure 215.

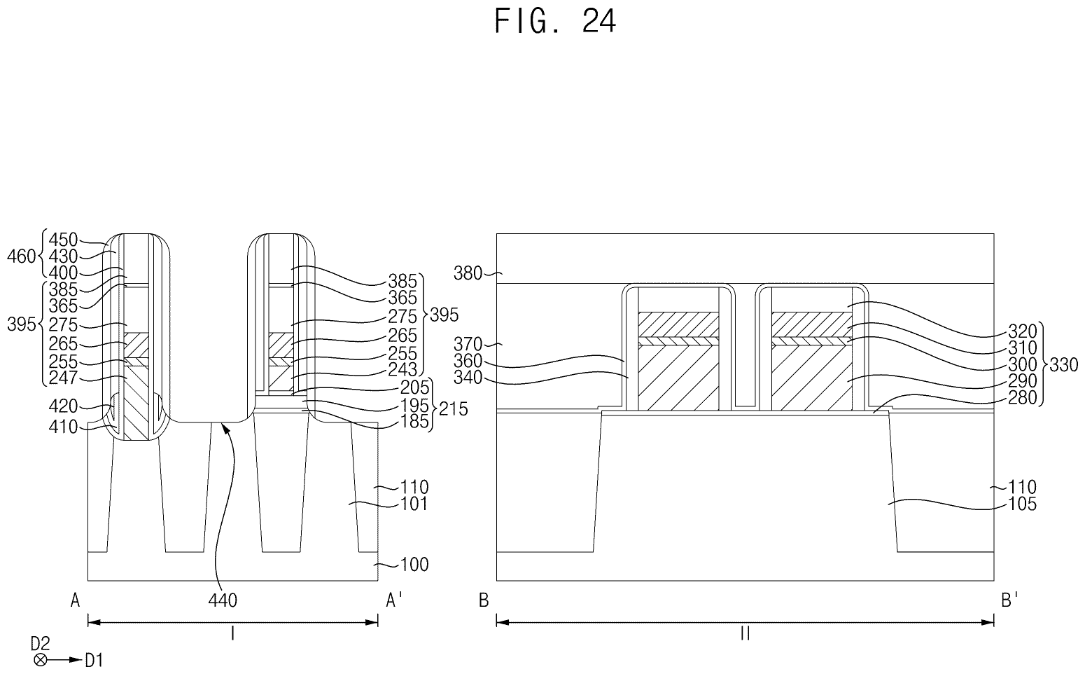

Referring to FIG. 24, a third spacer layer may be formed on upper surfaces of the capping layer 380 and the capping pattern 385, an outer sidewall of the second spacer 430, portions of the upper surfaces of the fourth and fifth insulation patterns 410 and 420, and upper surfaces of the first active pattern 101, the isolation pattern 110 and the first gate mask 160 exposed by the second opening 440. The third spacer layer may be anisotropically etched to form a third spacer 450 covering the outer sidewall of the second spacer 430.

The first to third spacers 400, 430 and 450 sequentially stacked on the sidewall of the bit line structure 395 in the horizontal direction on the first region I of the substrate 100 may be referred to as a preliminary spacer structure 460.

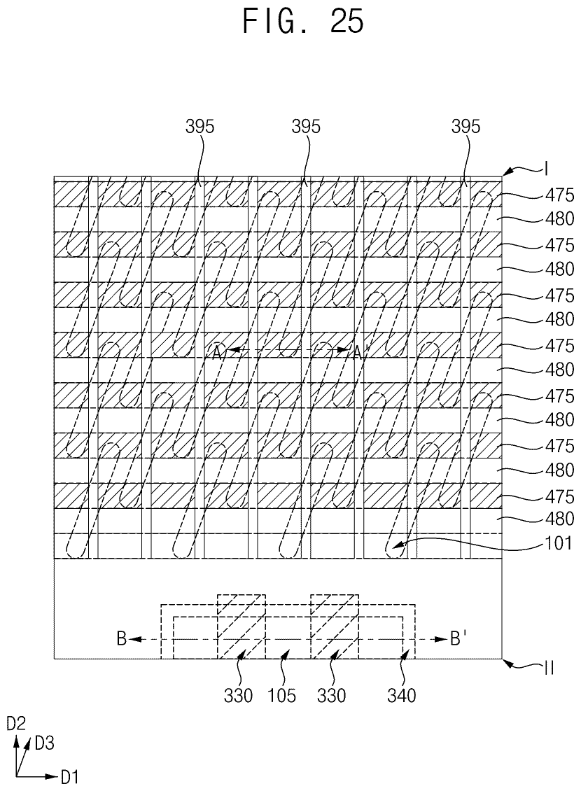

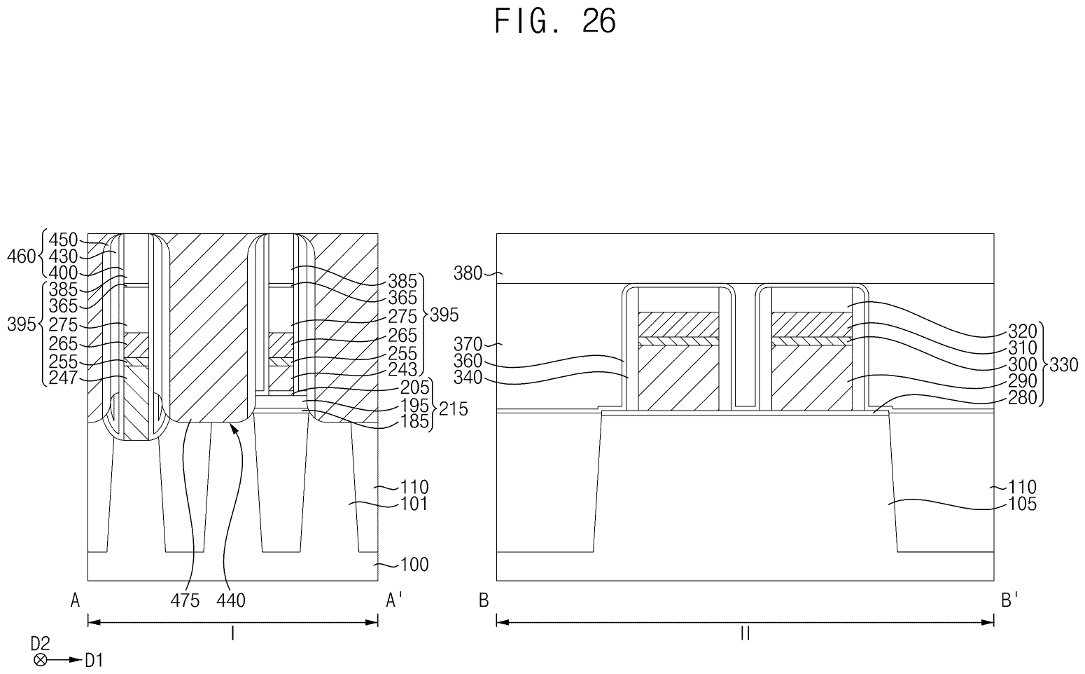

Referring to FIGS. 25 and 26, a preliminary lower contact plug layer may be formed to fill the second opening 440 on first region I of the substrate 100 to a sufficient height, and an upper portion of the preliminary lower contact plug layer may be planarized until the upper surfaces of the capping layer 380 and the capping pattern 385 are exposed to form a lower contact plug 475 in the second opening 440.

The lower contact plug 475 may extend in the second direction D2 between neighboring ones of the bit line structures 395 in the first direction D1 on the first region I of the substrate 100, and a plurality of lower contact plug 475 may be spaced apart from each other in the first direction D1.

A second mask including a plurality of third openings, each of which may extend in the first direction D1, spaced apart from each other in the second direction D2 may be formed on the capping layer 380 and the lower contact plug 475, and the lower contact plug 475 may be etched using the second mask as an etching mask to form a fourth opening.

In some example embodiments, each of the third openings may overlap the first gate structures 170 in the vertical direction. By the etching process, the fourth opening may be formed to expose the upper surface of the first gate mask 160 of the first gate structure 170. Thus, the lower contact plug 475 may be divided into a plurality of parts spaced apart from each other in the second direction D2. Each of the lower contact plugs 475 may contact an upper surface of an end portion of the first active pattern 101 extending in the third direction D3 in the third direction D3.

After removing the etching mask, a fence pattern 480 may be formed to fill the fourth opening. A plurality of fence patterns 480 may be spaced apart from each other in the second direction D2 between the bit line structures 395.

As illustrated above, the lower contact plugs 475 and the fence patterns 480 that may be alternately and repeatedly arranged in the second direction D2 may be formed by forming the preliminary lower contact plug layer extending in the second direction D2 between the bit line structures 395, planarizing the preliminary lower contact plug layer to form the lower contact plug 475, forming the fourth openings through the lower contact plug 475 that are spaced apart from each other in the second direction D2, and filling the fourth opening by the fence pattern 480, however, the inventive concepts may not be limited thereto.

In some example embodiments, the lower contact plugs 475 and the fence patterns 480 that may be alternately and repeatedly arranged in the second direction D2 may be formed by forming a fence layer extending in the second direction D2 between the bit line structures 395, forming fifth openings through the fence layer spaced apart from each other in the second direction D2 to divide the fence layer into the fence patterns 480, forming the preliminary lower contact plug layer on the fence layer to fill the fifth openings, and planarizing the lower contact plug layer to form the lower contact plugs 475.

In some example embodiments, the lower contact plugs 475 and the fence patterns 480 that may be alternately and repeatedly arranged in the second direction D2 may be formed by forming a sacrificial layer including oxide (e.g., silicon oxide) and extending in the second direction D2 between the bit line structures 395, forming the fence patterns 480 through the sacrificial layer spaced apart from each other in the second direction D2, removing the sacrificial layer to form sixth openings, forming the preliminary lower contact plug layer to fill the sixth openings, and planarizing the preliminary lower contact plug layer to form the lower contact plugs 475.

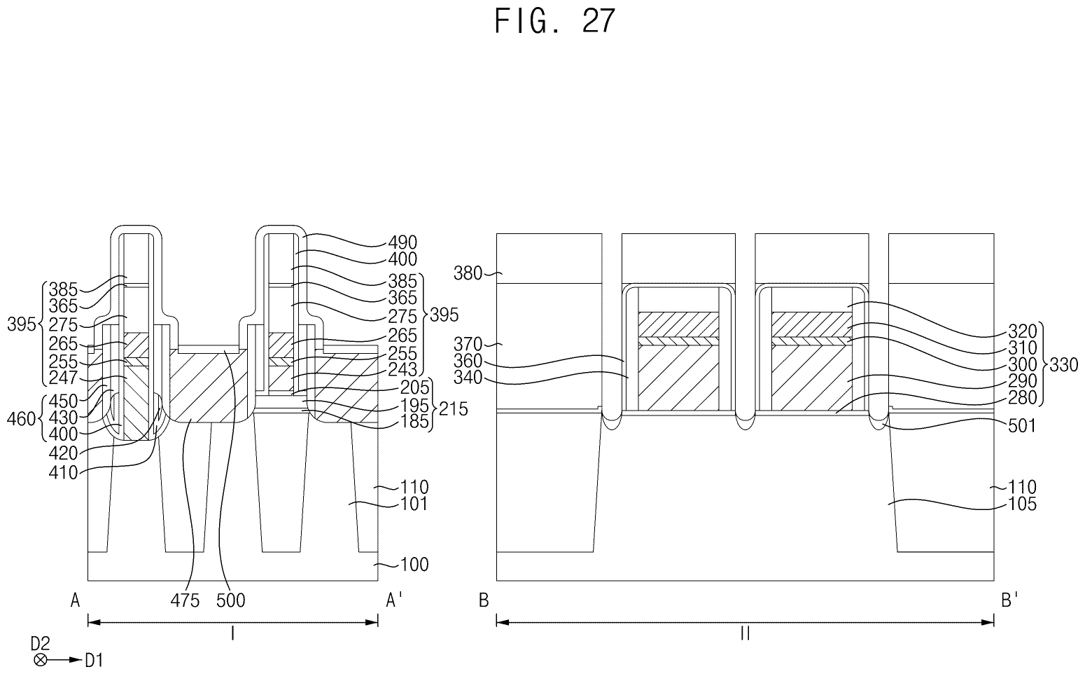

Referring to FIG. 27, an upper portion of the lower contact plug 475 may be removed to expose an upper portion of the preliminary spacer structure 460 on the sidewall of the bit line structure 395, and upper portions of the second and third spacers 430 and 450 of the exposed preliminary spacer structure 460 may be removed.

An upper portion of the lower contact plug 475 may be additionally removed. Thus, an upper surface of the lower contact plug 475 may be lower than upper surfaces of the second and third spacers 430 and 450.

A fourth spacer layer may be formed on the bit line structure 395, the preliminary spacer structure 460, the fence pattern 480 and the lower contact plug 475, and may be anisotropically etched to form a fourth spacer 490 covering an upper portion of the preliminary spacer structure 460 on the sidewall of the bit line structure 395, and the upper surface of the lower contact plug 475 may be exposed by the etching process. Additionally, the insulating interlayer 370 and the capping layer 380 may be etched to form a contact hole exposing an upper surface of the second active pattern 105 adjacent to the second gate structure 330. In some example embodiments, a plurality of contact holes may be formed to be spaced apart from each other in the first and second directions D1 and D2.

A first ohmic contact pattern 500 may be formed on the exposed upper surface of the lower contact plug 475, and a second ohmic contact pattern 501 may be formed on the exposed upper surface of the second active pattern 105. In some example embodiments, the first and second ohmic contact patterns 500 and 501 may be formed by forming a first metal layer on the capping pattern 385, the fourth spacer 490, the lower contact plug 475 and the second active pattern 105, performing a heat treatment thereon, and removing an unreacted portion of the first metal layer.

The first ohmic contact pattern 500 may be formed only on the exposed upper surface of the lower contact plug 475, but the inventive concepts are not limited thereto. That is, during the heat treatment process, the metal of the first metal layer may diffuse in the horizontal direction, so that the first ohmic contact pattern 500 may be also formed on the upper surface of the lower contact plug 475 covered by the fourth spacer 490.

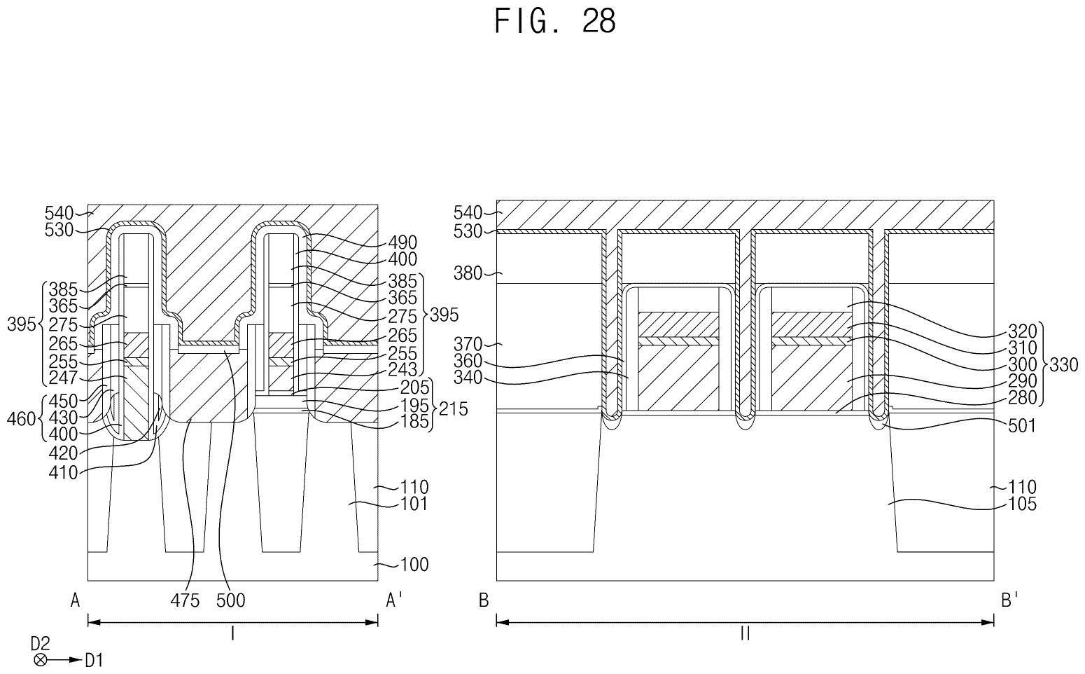

Referring to FIG. 28, a second barrier layer 530 may be formed on the capping pattern 385, the fence pattern 480, the fourth spacer 490, the first ohmic contact pattern 500 and the lower contact plug 475 on the first region I of the substrate 100, and the capping layer 380, an inner sidewall of the contact hole and the second ohmic contact pattern 501 on the second region II of the substrate 100, and a second metal layer 540 may be formed on the second barrier layer 530 to fill a space between the bit line structures 395 and the contact hole.

Referring to FIGS. 29 and 30, the second metal layer 540 and the second barrier layer 530 may be patterned.

Accordingly, a first upper contact plug 549 may be formed on the first region I of the substrate 100, and a wiring 605 and a second upper contact plug 607 may be formed on the second region II of the substrate 100. A seventh opening 547 may be formed between the first upper contact plug 549, the wiring 605 and the second upper contact plug 607.

The seventh opening 547 may be formed by partially removing not only the second metal layer 540 and the second barrier layer 530 but also the capping pattern 385, the first etch stop pattern 365, the third mask 275, the fourth spacer 490, the fence pattern 480 and the preliminary spacer structure 460 on the first region I of the substrate 100, and the first etch stop layer 360 and the capping layer 380 on the second region II of the substrate 100. The seventh opening 547 may expose the upper surface of the second spacer 430.

As the seventh opening 547 is formed, the second metal layer 540 and the second barrier layer 530 may be respectively transformed into a first metal pattern 545 and a fourth barrier pattern 535 covering a lower surface of the first metal pattern 545, which may collectively form the first upper contact plug 549 on the first region I of the substrate 100.

The lower contact plug 475, the ohmic contact pattern 500 and the first upper contact plug 549 sequentially stacked on the first region I of the substrate 100 may collectively form a contact plug structure.

The second metal layer 540 and the second barrier layer 530 not overlapping the contact hole in the third direction D3 may be respectively transformed into a second metal pattern 595 and a fifth barrier pattern 585 covering a lower surface of the second metal pattern 595, which may collectively form the wiring 605 on the second region II of the substrate 100.

The second metal layer 540 and the second barrier layer 530 overlapping the contact hole in the third direction D3 may be respectively transformed into a third metal pattern 597 and a sixth barrier pattern 587 covering a lower surface of the third metal pattern 597, which may collectively form the second upper contact plug 607 on the second region II of the substrate 100.

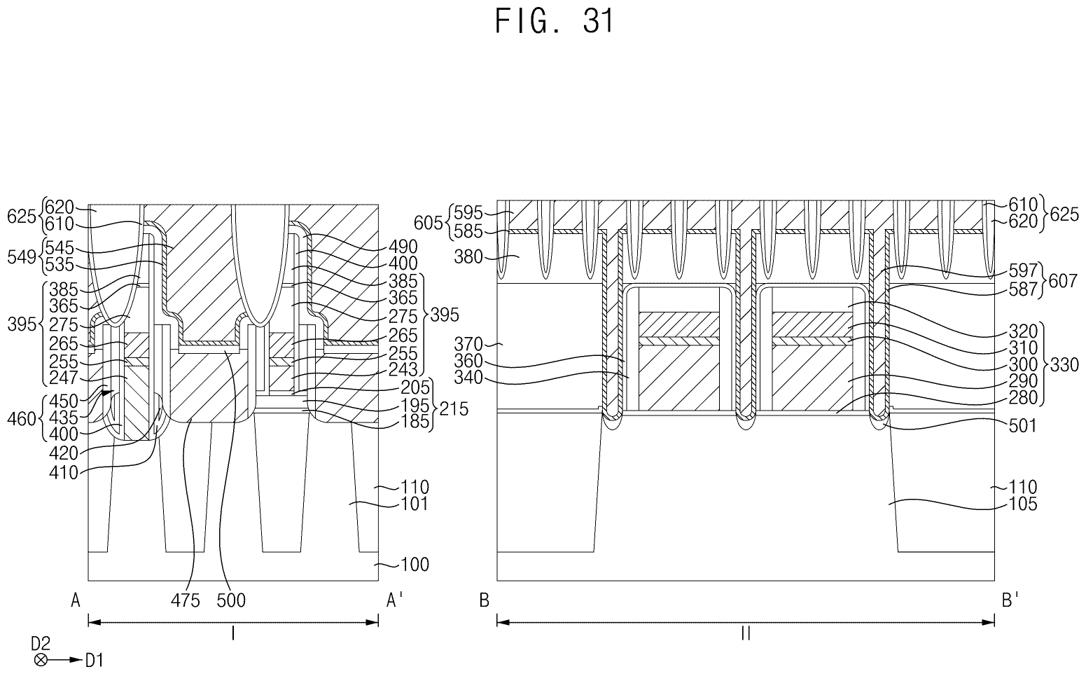

Referring to FIG. 31, the second spacer 430 may be removed to form an air gap connected to the seventh opening 547. The second spacer 430 may be removed by, e.g., a wet etching process.

In some example embodiments, not only a first portion of the second spacer 430 on the sidewalls of the bit line structure 395, which is directly exposed by the seventh opening 547, but also a second portion of the second spacer 430, which is parallel to the first portion in the horizontal direction, may be removed. That is, not only a portion of the seventh spacer 430 exposed by the seventh opening 547 not to be covered by the first upper contact plug 549 but also a portion of the second spacer 430 covered by the first upper contact plug 549 may be removed.

A second insulation pattern structure 625 may be formed to fill the seventh opening 547.

In some example embodiments, the second insulation pattern structure 625 may include sixth and seventh insulation layers 610 and 620 sequentially stacked. The sixth insulation layer 610 may include a material having a poor gap filling characteristic, and thus the air gap may not be filled with the sixth insulation layer 610, but may remain, which may be referred to as an air spacer 435. The fifth and seventh spacers 400 and 450 and the air spacer 435 may collectively form a spacer structure 465. The air spacer 435 may be a spacer including an air. The seventh insulation layer 620 may include oxide (e.g., silicon oxide) or nitride (e.g., a silicon nitride).

Referring to FIGS. 1 to 3 again, a capacitor 670 may be formed to contact an upper surface of the first upper contact plug 549.

For example, a second etch stop layer 630 and a mold layer may be sequentially formed on the first upper contact plug 549, the second insulation pattern structure 625 and the wirings 605, and may be partially etched to form an eighth opening partially exposing an upper surface of the first upper contact plug 549.

A lower electrode layer may be formed on the exposed upper surface of the first upper contact plug 549 and the mold layer to fill the eighth opening, and may be planarized until an upper surface of the mold layer is exposed to form a lower electrode 640 having a pillar shape. In some example embodiments, the lower electrode 640 may be formed to have a cylindrical shape. The mold layer may be removed by, for example, a wet etching process.

A dielectric layer 650 may be formed on a surface of the lower electrode 640 and an upper surface of the second etch stop layer 630, and an upper electrode 660 may be formed on the dielectric layer 650 to form the capacitor 670 including the lower electrode 640, the dielectric layer 650 and the upper electrode 660 on the first region I of the substrate 100.

Contact plugs and upper wirings may be further formed on the substrate 100 to be electrically connected to the capacitor 670, the bit line structure 395 and the wirings 605, so that the fabrication of the semiconductor device may be completed.

As illustrated above, the third conductive layer 240 may be formed on the substrate 100 including the first region I and the second region II, the first mask 241 covering the second portion of the third conductive layer 240 on the second region II of the substrate 100 may be formed, the first doping process may be performed on the first portion of the third conductive layer 240 on the first region I of the substrate 100 which is not covered by the first mask 241, the first mask 241 may be removed, and the second doping process may be performed on the first and second portions of the third conductive layer 240. Accordingly, the doping concentration of impurities of the first portion of the third conductive layers 240 on the first region I may be greater than the doping concentration of impurities of the third conductive layer 240 on the second region II, and thus, the first doping concentration of impurities of the fifth conductive pattern 243 derived from the first portion of the third conductive layer 240 on the first region I may be greater than the second doping concentration of impurities derived from the second portion of the third conductive layer 240 on the second region II.

If the first doping process is not performed on the third conductive layer 240, doping concentrations of impurities of each of the fifth conductive pattern 243 of the bit line structure 395 and the third conductive pattern 290 of the second gate structure 330 may be determined only by the second doping process. Accordingly, the doping concentration of impurities of the fifth conductive pattern 243 and the third conductive pattern 290 cannot be independently adjusted based on the electrical characteristics of each of the bit line structure 395 and the second gate structure 330. For example, when the doping concentration of impurities is increased during the second doping process to lower the resistance of the bit line structure 395, the doping concentration of impurities of the third conductive pattern 290 of the second gate structure 330 may also increase, leading to increase of the threshold voltage of the second gate structure 330.

However, in the methods of manufacturing the semiconductor device according to some example embodiments, not only the second doping process, which is performed on the first and second portions of the third conductive layer 240, but also the first doping process, which is selectively performed only on the first portion of the third conductive layer 240 on the first region I of the substrate 100, may be performed. Accordingly, by the first doping process, the first doping concentration of impurities of the fifth conductive pattern 243 of the bit line structure 395 and the second doping concentration of impurities of the third conductive pattern 290 of the second gate structure 330 may be adjusted independently, and thus, electrical characteristics of the semiconductor device may be improved.

Additionally, after forming the first mask 241 covering the second portion of the third conductive layer 240 on the second region II of the substrate 100, the upper portion of the first portion of the third conductive layer 240 on the first region I of the substrate 100, which is not covered by the first mask 241, may be removed. Hence, height of the fifth conductive pattern 243 may be lowered to reduce the aspect ratio of the bit line structure 395 including the fifth conductive pattern 243, thereby lowering overall process difficulty. Also, as the aspect ratio of the bit line structure 395 decreases, parasitic capacitance between the bit line structure 395 and the contact plug structure may also decrease.

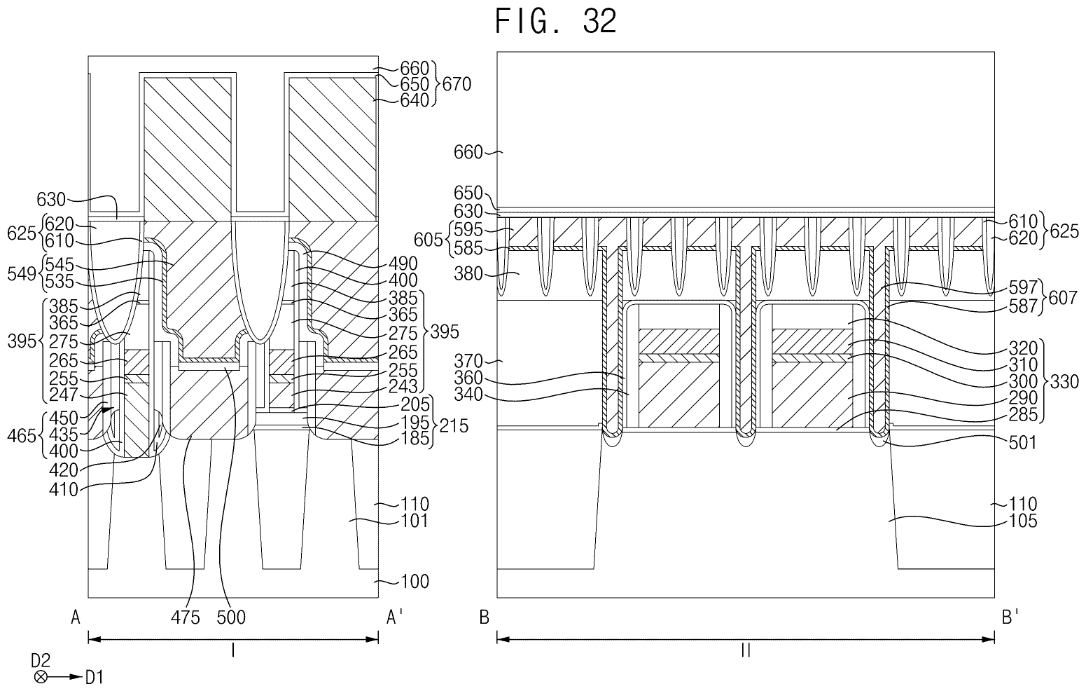

FIG. 32 is a cross-sectional view illustrating a semiconductor device in accordance with an example embodiment.

The semiconductor device may be substantially the same as or similar to that of FIGS. 1 to 3, except for the second gate structure 330 including a third gate insulation pattern 285 instead of the second gate insulation pattern 280.

Referring to FIG. 32, the second gate structure 330 may include the third gate insulation pattern 285, the second barrier pattern 300, the fourth conductive pattern 310 and the second gate mask 320.

In some example embodiments, the third gate insulation pattern 285 may include metal oxide having a high dielectric constant, for example, hafnium oxide (HfO₂), tantalum oxide (Ta₂O₅), zirconium oxide (ZrO₂), etc.

In an example embodiment, an upper surface of the fourth conductive pattern 310 of the second gate structure 330 and an upper surface of the seventh conductive pattern 265 of the bit line structure 395 may be substantially coplanar to each other.

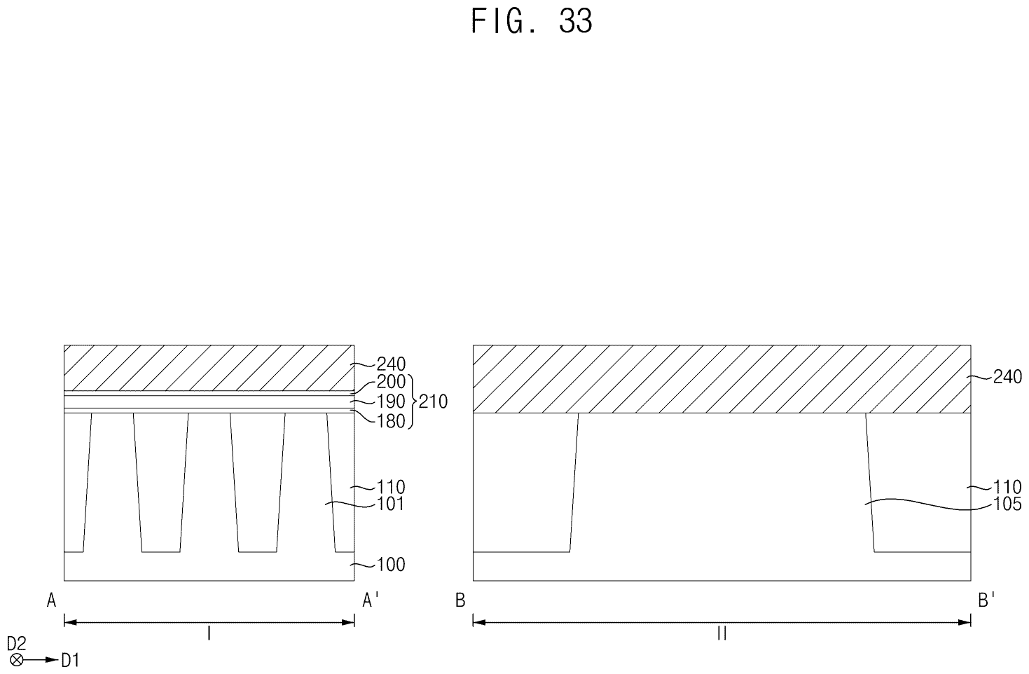

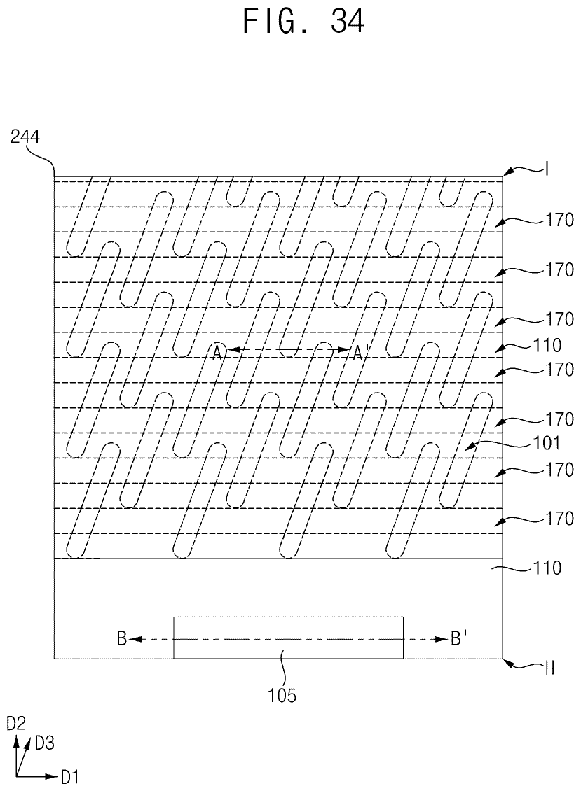

FIGS. 33 to 37 are a plan view and cross-sectional views illustrating a method of manufacturing a semiconductor device according to an example embodiment. Specifically, FIG. 34 is the plan views, and FIGS. 33 and 35-37 include cross-sectional views taken along lines A-A′ and B-B′, respectively, of corresponding plan views. This method may include processes substantially the same as or similar to those illustrated with reference to FIGS. 4 to 31 and FIGS. 1 to 3, and thus repeated explanations thereof are omitted herein.

Referring to FIG. 33, processes substantially the same as or similar to those illustrated with reference to FIGS. 4 to 10 may be performed.

That is, the first insulation layer structure 210 may be formed on the first and second regions I and II of the substrate 100, and the portion of the first insulation layer structure 210 on the second region II of the substrate 100 may be removed. However, unlike the processes described with reference to FIGS. 9 and 10, the third conductive layer 240 may be formed on the first insulation layer structure 210 on the first region I of the substrate 100 and the second active pattern 105 and the isolation pattern 110 on the second region II of the substrate 100. The third conductive layer 240 may include, for example, polysilicon doped with n-type impurities, for example, phosphorus (P), arsenic (As), etc.

In an example embodiment, the third conductive layer 240 may be formed by forming the preliminary third conductive layer 240a including undoped polysilicon, and performing an IIP process and/or a GPD process thereon. In another example embodiment, the third conductive layer 240 may be formed by performing a deposition process using a source gas of silicon and a source gas of n-type impurities.

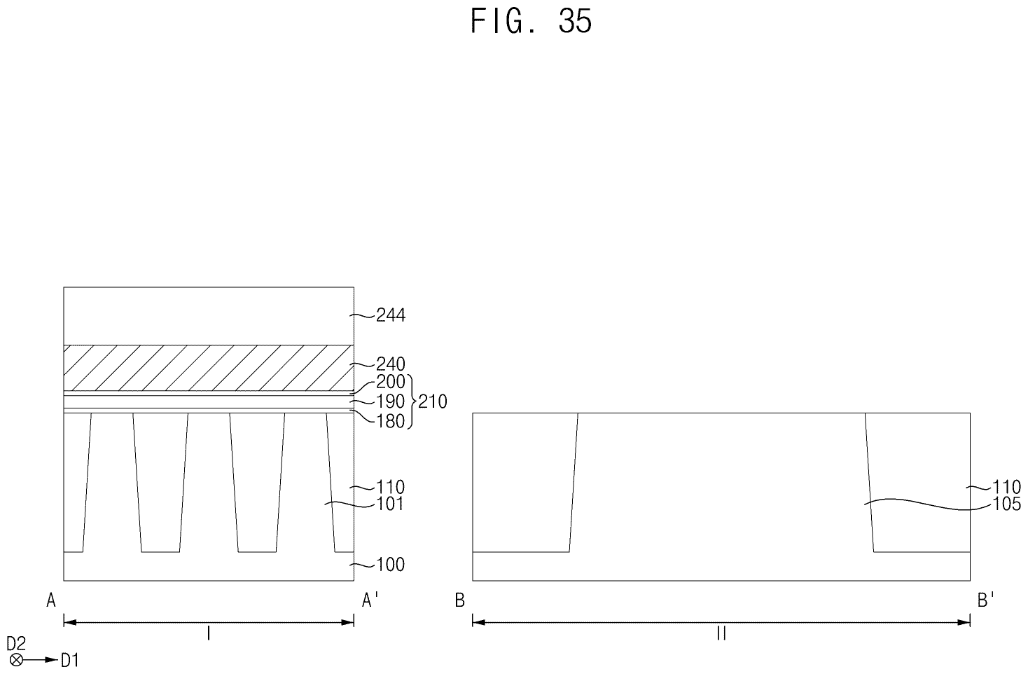

Referring to FIGS. 34 and 35, a fourth mask 244 may be formed on the first portion of the third conductive layer 240 on the first region I of the substrate 100, and the second portion of the third conductive layer 240 on the second region II of the substrate 100 may be removed.

Accordingly, the upper surfaces of the second active pattern 105 and the isolation pattern 110 on the second region II of the substrate 100 may be exposed.

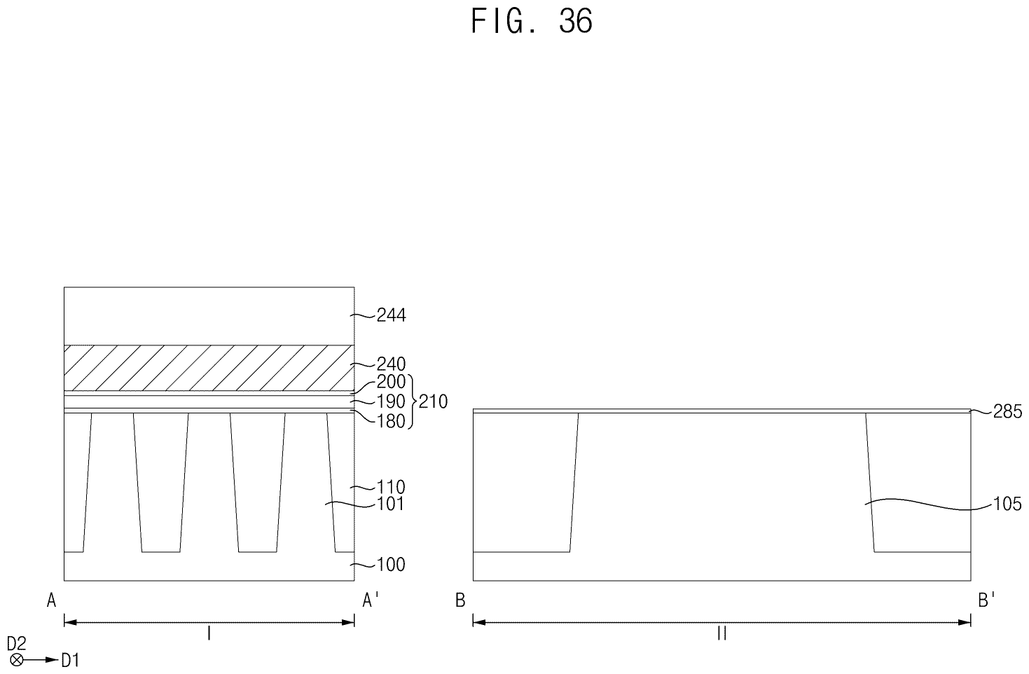

Referring to FIG. 36, a third gate insulation pattern 285 may be formed on the first and second regions I and II of the substrate 100, and a portion of the third gate insulation pattern 285 on the first region I of the substrate 100 may be removed.

The third gate insulation pattern 285 may include metal oxide having a high dielectric constant, for example, hafnium oxide (HfO₂), tantalum oxide (Ta₂O₅), zirconium oxide (ZrO₂), etc. In some example embodiments, the third gate insulation pattern 285 may be formed by a deposition process.

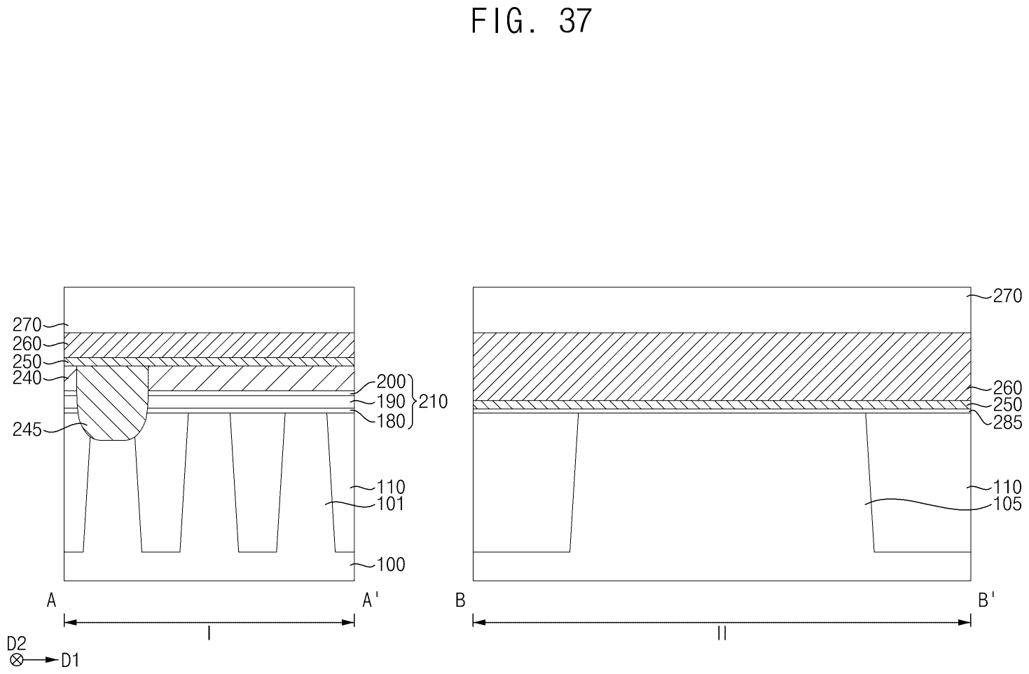

Referring to FIG. 37, after removing the fourth mask 244, the first barrier layer 250, the fifth conductive layer 260 and the third mask layer 270 may be sequentially formed on the third conductive layer 240 and the third gate insulation pattern 285.

Thereafter, manufacturing of the semiconductor device may be completed by performing processes substantially the same as or similar to the processes illustrated with reference to FIGS. 18 to 31 and FIGS. 1 to 3.

While some example embodiments have been particularly shown and described, it will be understood by one of ordinary skill in the art that variations in form and detail may be made therein without departing from the spirit and scope of the claims.

What is claimed is:

1. A semiconductor device, comprising:
a substrate including a first region and a second region;
a first active pattern and a second active pattern on the first and second regions of the substrate, respectively;
a bit line structure extending in a horizontal direction substantially parallel to an upper surface of the substrate, the bit line structure including
a lower conductive structure having first conductive patterns and second conductive patterns alternately and repeatedly arranged in the horizontal direction, the first conductive patterns containing polysilicon doped with first impurities and second impurities, and the second conductive patterns containing polysilicon doped with third impurities, and
an upper conductive structure on the lower conductive structure and including a third conductive pattern;
a gate structure on the second active pattern, the gate structure including a gate insulation pattern and a fourth conductive pattern sequentially stacked in a vertical direction substantially perpendicular to the upper surface of the substrate, the fourth conductive pattern including polysilicon doped with the second impurities;
a contact plug structure on each of opposite ends of the first active pattern; and
a capacitor on the contact plug structure.

2. The semiconductor device of claim 1, wherein a first doping concentration, which is a sum of a doping concentration of the first impurities and a doping concentration of the second impurities of a respective one of the first conductive patterns, is greater than a second doping concentration of the second impurities of the fourth conductive pattern.

3. The semiconductor device of claim 2, wherein the first doping concentration is about 1.4 to about 5 times the second concentration.

4. The semiconductor device of claim 2, wherein a third doping concentration of the third impurities of a respective one of the second conductive patterns is greater than the first concentration.

5. The semiconductor device of claim 1, wherein the first and second impurities are different from each other.

6. The semiconductor device of claim 1, wherein the first and second impurities are same as each other.

7. The semiconductor device of claim 1, wherein a lower surface of a respective one of the second conductive patterns contacts an upper surface of a central portion of the first active pattern, and is lower than a lower surface of a respective one of the first conductive patterns.

8. The semiconductor device of claim 1, wherein the upper conductive structure includes a first barrier pattern on the lower conductive structure and the third conductive pattern on the first barrier pattern, and
wherein the gate structure includes a second barrier pattern and a fifth conductive pattern on the fourth conductive pattern, and
wherein the first barrier pattern and the third conductive pattern contain substantially same materials as the second barrier pattern and the fifth conductive pattern, respectively.

9. A semiconductor device, comprising:
a substrate including a first region and a second region;
a first active pattern and a second active pattern on the first and second regions of the substrate, respectively;
a bit line structure including
a lower conductive structure extending in a horizontal direction substantially parallel to an upper surface of the substrate, the lower conductive structure contacting an upper surface of a central portion of the first active pattern,
a first barrier pattern on the lower conductive structure, and
a third conductive pattern on the first barrier pattern;
a gate structure on the second active pattern, the gate structure including a gate insulation pattern, a fourth conductive pattern, a second barrier pattern and a fifth conductive pattern sequentially stacked in a vertical direction substantially perpendicular to the upper surface of the substrate, and an upper surface of the fourth conductive pattern being higher than an upper surface of the lower conductive structure;
a contact plug structure on each of opposite ends of the first active pattern; and
a capacitor on the contact plug structure.

10. The semiconductor device of claim 9, wherein the lower conductive structure has first conductive patterns and second conductive patterns alternately and repeatedly arranged in the horizontal direction, and the second conductive patterns contact the upper surface of the central portion of the first active pattern.

11. The semiconductor device of claim 10, wherein lower surfaces of the second conductive patterns are lower than lower surfaces of the first conductive patterns.

12. The semiconductor device of claim 10, wherein the first conductive patterns, the second conductive patterns and the fourth conductive pattern contain n-type impurities, and a first doping concentration of n-type impurities of a respective one of the first conductive patterns is greater than a second doping concentration of n-type impurities of the fourth conductive pattern.

13. The semiconductor device of claim 12, wherein the first doping concentration is about 1.4 to about 5 times the second doping concentration.

14. The semiconductor device of claim 12, wherein a third doping concentration of n-type impurities of a respective one of the second conductive patterns is greater than the first doping concentration.

15. The semiconductor device of claim 9, wherein the first barrier pattern and the third conductive pattern contain same materials as the second barrier pattern and the fifth conductive pattern, respectively.

16. A semiconductor device, comprising:
a substrate including a first region and a second region;
a first active pattern and a second active pattern on the first and second regions of the substrate, respectively;
a bit line structure including
a lower conductive structure extending in a horizontal direction substantially parallel to an upper surface of the substrate, the lower conductive structure having first conductive patterns and second conductive patterns alternately and repeatedly arranged in the horizontal direction, a respective one of the second conductive patterns contacting an upper surface of a central portion of the first active pattern,
a first barrier pattern on the lower conductive structure, and
a third conductive pattern on the first barrier pattern;
a gate structure on the second active pattern, the gate structure including a gate insulation pattern, a second barrier pattern and a fourth conductive pattern sequentially stacked in a vertical direction substantially perpendicular to the upper surface of the substrate;
a contact plug structure on each of opposite ends of the first active pattern; and
a capacitor on the contact plug structure, and
wherein the first barrier pattern and the second conductive pattern contain substantially same materials as the second barrier pattern and the fourth conductive pattern, respectively.

17. The semiconductor device of claim 16, wherein the gate insulation pattern contains a high dielectric material.

18. The semiconductor device of claim 16, wherein each of the first and second barrier patterns contain metal nitride or metal silicon nitride.

19. The semiconductor device of claim 16, wherein an upper surface of the third conductive pattern and upper surfaces of the second conductive patterns are substantially coplanar to each other.

20. The semiconductor device of claim 16, wherein lower surfaces of the second conductive patterns are lower than lower surfaces of the first conductive patterns.
